(19) United States
(12) Patent Application Publication
(10) Pub. No.: US 2025/0008790 A1
(43) Pub. Date: Jan. 2, 2025

(54) Display Panel and Display Apparatus

(71) Applicant: BOE Technology Group Co., Ltd., Beijing (CN)

(72) Inventors: Xing ZHANG, Beijing (CN); Pan XU, Beijing (CN); Ying HAN, Beijing (CN); Chengyuan LUO, Beijing (CN); Donghui ZHAO, Beijing (CN); Guangshuang LV, Beijing (CN); Cheng XU, Beijing (CN)

(21) Appl. No.: 18/277,228

(22) PCT Filed: Nov. 30, 2022
(86) PCT No.: PCT/CN2022/135410

§ 371 Date: Aug. 15, 2023

(51) Int. Cl. H10K 59/131

(52) U.S. Cl. CPC H10K 59/131

(57) ABSTRACT

A display panel and a display apparatus are provided, the display panel includes a substrate and a drive circuit layer, the drive circuit layer includes a pixel drive circuit (PE) and a first scan signal line (G1), the pixel drive circuit is electrically connected with the first scan signal line (G1), and the first scan signal lines (G1) connected with adjacent rows of pixel drive circuits are electrically isolated; the drive circuit layer further includes a first signal line located in a non-display region (AA′) and a second signal line corresponding to the first signal line, the first signal line is configured to supply a signal to the first scan signal line (G1), an orthographic projection of the first signal line on the substrate at least partially overlaps an orthographic projection of the corresponding second signal line on the substrate.

### CROSS-REFERENCE TO RELATED APPLICATION

The present application is a U.S. National Phase Entry of International Application No. PCT/CN2022/135410 having an international filing date of Nov. 30, 2022. The above-identified application is hereby incorporated by reference.

### TECHNICAL FIELD

The present disclosure relates to, but is not limited to, the field of display technologies, and more particularly, to a display panel and a display apparatus.

### BACKGROUND

An Organic Light Emitting Diode (OLED for short) and a Quantum dot Light Emitting Diode (QLED for short) are active light emitting display devices and have advantages such as self-luminescence, a wide viewing angle, a high contrast ratio, low power consumption, an extremely high response speed, lightness and thinness, flexibility, and a low cost. With constant development of display technologies, a flexible display apparatus (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described in the present disclosure in detail. The summary is not intended to limit the protection scope of claims.

In a first aspect, the present disclosure provides a display panel including: a substrate and a drive circuit layer disposed on the substrate, the substrate includes a display region and a non-display region, the drive circuit layer includes: a plurality of pixel drive circuits disposed in the display region and a plurality of first scan signal lines disposed in the display region and the non-display region, the first scan signal lines extend at least partially in a first direction, the pixel drive circuits are electrically connected with the first scan signal lines, and the first scan signal lines connected with adjacent rows of pixel drive circuits are electrically isolated;
the drive circuit layer further includes first signal lines located in the non-display region and second signal lines corresponding to the first signal lines, the first signal lines are electrically connected with the first scan signal lines and configured to provide a signal to the first scan signal line, an orthographic projection of the first signal lines on the substrate at least partially overlaps an orthographic projection of the corresponding second signal lines on the substrate;
the resistance of the first signal lines electrically connected to adjacent first scan signal lines are substantially equal and/or the capacitance value between the first signal lines electrically connected to adjacent first scan signal lines and the corresponding second signal lines are substantially equal.

In an exemplary embodiment, the drive circuit layer further includes: a plurality of second scan signal lines, a plurality of third scan signal lines, a plurality of light emitting signal lines, and a plurality of reference signal lines disposed in the display region and the non-display region, the pixel drive circuits are electrically connected with the second scan signal lines, the third scan signal lines, the light emitting signal lines, and the reference signal lines, respectively, the second scan signal lines, the third scan signal lines, the light emitting signal lines, and the reference signal lines extend at least partially in the first direction;
an i-th row of pixel drive circuits are electrically connected to an i-th first scan signal line, an i-th second scan signal line, an i-th third scan signal line, an i-th light emitting signal line, and an i-th reference signal line, respectively, 1≤i≤M, and M is the total number of rows of the pixel drive circuits;
the i-th third scan signal line, the i-th reference signal line, the i-th second scan signal line, the i-th first scan signal line and the i-th light emitting signal line are arranged sequentially along a second direction, the i-th third scan signal line is located on a side of the i-th reference signal line close to an (i−1)-th light emitting signal line, the i-th light emitting signal line is located on a side of the i-th first scan signal line close to an (i+1)-th third scan signal line, and the second direction intersects with the first direction;
the second signal line is electrically connected with at least one of the second scan signal line, the third scan signal line, and the light emitting signal line.

In an exemplary embodiment, the drive circuit layer further includes: M first scan output lines, M12 second scan output lines, M/2 third scan output lines, M reference output lines and M/2 light emitting output lines located in the non-display region, the first scan output lines, the second scan output lines, the third scan output lines, the reference output lines and the light emitting output lines extend at least partially in the first direction;
an i-th first scan output line is electrically connected with an i-th first scan signal line, an i-th reference output line is electrically connected with the i-th reference signal line, a j-th second scan output line is electrically connected with a (2j−1)-th second scan signal line and a 2j-th second scan signal line respectively, a j-th third scan output line is electrically connected with a (2j−1)-th third scan signal line and a 2j-th third scan signal line respectively, a j-th light emitting output line is electrically connected with a (2j−1)-th light emitting signal line and a 2j-th light emitting signal line respectively, 1≤j≤M/2; a (2j−1)-th reference output line, a (2j−1)-th first scan output line, the j-th second scan output line, the j-th third scan output line, a 2j-th reference output line, the j-th light emitting output line and a 2j-th first scan output line are sequentially arranged in the second direction.

In an exemplary embodiment, the drive circuit layer further includes: a reference power supply line located in the non-display region and a data signal line and a first power supply line located at least partially in the display region, the reference power supply line, the data signal line and the first power supply line extend at least partially in a second direction; the pixel drive circuit is electrically connected with the data signal line and the first power supply line, respectively, and an orthographic projection of the reference power supply line on the substrate at least partially overlaps an orthographic projection of the reference output line on the substrate, and the reference power supply line is electrically connected with the reference output line.

In an exemplary embodiment, the drive circuit layer includes: a first conductive layer and a second conductive layer sequentially stacked on the substrate; the first conductive layer at least includes a first scan signal line, a second scan signal line, a third scan signal line, a light emitting signal line and a reference power supply line; the second conductive layer at least includes a first scan output line, a second scan output line, a third scan output line, a reference output line, a light emitting output line, a data signal line and a first power supply line.

In an exemplary embodiment, the first conductive layer and the second conductive layer have substantially equal square resistance.

In an exemplary embodiment, the first conductive layer and the second conductive layer are made of the same material and thickness.

In an exemplary embodiment, the distances between the boundaries of the first signal lines electrically connected to the adjacent first scan signal lines close to the display region and the display region are substantially equal, and the average lengths of the first signal lines electrically connected to the adjacent first scan signal lines in the second direction are substantially equal.

In an exemplary embodiment, areas of an overlapping region between the first signal lines electrically connected to the adjacent first scan signal lines and corresponding second signal lines are substantially equal.

In an exemplary embodiment, the drive circuit layer further includes: a first signal connection line located in the first conductive layer, the first signal connection line extends in the second direction and electrically connected with the (2j−1)-th third scan signal line and the 2j-th third scan signal line, respectively; an orthographic projection of the first signal connection line on the substrate at least partially overlaps an orthographic projection of the (2j−1)-th first scan output line on the substrate; an orthographic projection of the j-th third scan output line on the substrate at least partially overlaps an orthographic projection of the 2j-th third scan signal line on the substrate, and the j-th third scan output line is electrically connected with the 2j-th third scan signal line.

In an exemplary embodiment, the drive circuit layer further includes: a second signal connection line located in the second conductive layer, the second signal connection line extends in the first direction; the 2j-th second scan signal line includes a first scan connection part and a second scan connection part connected with each other, wherein the first scan connection part extends in the first direction, the second scan connection part extends in the second direction, and the first signal connection line is located on a side of the second scan connection part close to the display region; an orthographic projection of the second scan connection part on the substrate at least partially overlaps an orthographic projection of the (2j−1)-th first scan output line, the j-th second scan output line, the j-th third scan output line and the second signal connection line on the substrate, and the second scan connection part is electrically connected with the j-th second scan output line and the second signal connection line, respectively; an orthographic projection of the second signal connection line on the substrate at least partially overlaps an orthographic projection of the (2j−1)-th second scan signal line and the first signal connection line on the substrate, and the second signal connection line is electrically connected with the (2j−1)-th second scan signal line.

In an exemplary embodiment, the drive circuit layer further includes: a third signal connection line located in the second conductive layer, the third signal connection line extends in the first direction; the 2j-th light emitting signal line includes a first light emitting connection part and a second light emitting connection part connected with each other, wherein the first light emitting connection part extends in the first direction, the second light emitting connection part extends in the second direction, and the second light emitting connection part is located between the reference power supply line and the second scan connection part; an orthographic projection of the second light emitting connection part on the substrate at least partially overlaps an orthographic projection of the j-th light emitting output line, the j-th third scan output line, the 2j-th first scan output line and the third signal connection line on the substrate, and the second light emitting connection part is electrically connected with the j-th light emitting output line and the third signal connection line, respectively; an orthographic projection of the third signal connection line on the substrate at least partially overlaps an orthographic projection of the (2j−1)-th light emitting signal line, the first signal connection line and the second scan connection part on the substrate and the third signal connection line is electrically connected with the (2j−1)-th light emitting signal line; the length of the overlapping region of the second light emitting connection part and the 2j-th first scan output line along the first direction is greater than the length of the first light emitting connection part along the second direction.

In an exemplary embodiment, the first signal lines electrically connected with the i-th first scan signal line includes: the i-th first scan output line; the second signal lines corresponding to the first signal lines electrically connected with a (2j−1)-th first scan signal line include the first signal connection line and the 2j-th second scan signal line, and the second signal lines corresponding to the first signal lines electrically connected with a 2j-th first scan signal line includes the 2j-th light emitting signal line.

In an exemplary embodiment, an orthographic projection of the (2j−1)-th reference output line on the substrate at least partially overlaps an orthographic projection of the first signal connection line and the (2j−1)-th reference signal line on the substrate, and the (2j−1)-th reference output line is electrically connected with the (2j−1)-th reference signal line; an orthographic projection of the 2j-th reference output line on the substrate at least partially overlaps an orthographic projection of the second scan connection part, the second light emitting connection part and a 2j-th reference signal line on the substrate, and the 2j-th reference output line is electrically connected with the 2j-th reference signal line.

In an exemplary embodiment, the drive circuit layer further includes: a first signal connection line located in the first conductive layer, the first signal connection line extends in the second direction and electrically connected with the (2j−1)-th third scan signal line and the 2j-th third scan signal line, respectively; an orthographic projection of the first signal connection line on the substrate at least partially overlaps an orthographic projection of the (2j−1)-th first scan output line and the 2j-th first scan output line on the substrate; an orthographic projection of the j-th third scan output line on the substrate at least partially overlaps an orthographic projection of the 2j-th third scan signal line on the substrate, and the j-th third scan output line is electrically connected with the 2j-th third scan signal line.

In an exemplary embodiment, the drive circuit layer further includes: a second signal connection line located at the first conductive layer, and a third signal connection line and a fourth signal connection line located at the second conductive layer, the second signal connection line extends in the second direction, the third signal connection line and the fourth signal connection line extend at least partially in the first direction, the second signal connection line is located on a side of the first signal connection line away from the display region; an orthographic projection of the second signal connection line on the substrate at least partially overlaps an orthographic projection of the (2j−1)-th first scan output line, the 2j-th first scan output line, the j-th second scan output line, the j-th third scan output line, the third signal connection line and the fourth signal connection line on the substrate, and the second signal connection line is electrically connected with the j-th second scan output line, the third signal connection line and the fourth signal connection line respectively; an orthographic projection of the third signal connection line on the substrate at least partially overlaps an orthographic projection of the first signal connection line and the (2j−1)-th second scan signal line on the substrate, and the third signal connection line is electrically connected with the (2j−1)-th second scan signal line; an orthographic projection of the fourth signal connection line on the substrate at least partially overlaps an orthographic projection of the first signal connection line and the 2j-th second scan signal line on the substrate, and the fourth signal connection line is electrically connected with the 2j-th second scan signal line.

In an exemplary embodiment, the drive circuit layer further includes: a fifth signal connection line located at the first conductive layer, and a sixth signal connection line and a seventh signal connection line located at the second conductive layer, the fifth signal connection line extends in the second direction, the sixth signal connection line and the seventh signal connection line extend at least partially in the first direction, the fifth signal connection line is located on a side of the second signal connection line away from the display region; an orthographic projection of the fifth signal connection line on the substrate at least partially overlaps an orthographic projection of the (2j−1)-th first scan output line, the 2j-th first scan output line, the j-th second scan output line, the j-th third scan output line, the j-th light emitting output line, the sixth signal connection line and the seventh signal connection line on the substrate, and the fifth signal connection line is electrically connected with the j-th light emitting output line, the sixth signal connection line and the seventh signal connection line respectively; an orthographic projection of the sixth signal connection line on the substrate at least partially overlaps an orthographic projection of the fifth signal connection line, the second signal connection line and the (2j−1)-th light emitting signal line on the substrate, and the sixth signal connection line is electrically connected with the (2j−1)-th light emitting signal line; an orthographic projection of the seventh signal connection line on the substrate at least partially overlaps an orthographic projection of the first signal connection line, the second signal connection line and the 2j-th light emitting signal line on the substrate, and the seventh signal connection line is electrically connected with the 2j-th light emitting signal line.

In an exemplary embodiment, the first signal lines electrically connected with the i-th first scan signal line includes: the i-th first scan output line; the second signal lines corresponding to the first signal lines electrically connected with the (2j−1)-th first scan signal line include the first signal connection line, the second signal connection line and the fifth signal connection line, and the second signal lines corresponding to the first signal lines electrically connected with the 2j-th first scan signal line include the first signal connection line, the second signal connection line and the fifth signal connection line.

In an exemplary embodiment, an orthographic projection of the (2j−1)-th reference output line on the substrate at least partially overlaps an orthographic projection of the first signal connection line, the second signal connection line, the fifth signal connection line and the (2j−1)-th reference signal line on the substrate, and the (2j−1)-th reference output line is electrically connected with the (2j−1)-th reference signal line; an orthographic projection of the 2j-th reference output line on the substrate at least partially overlaps an orthographic projection of the first signal connection line, the second signal connection line, the fifth signal connection line and the 2j-th reference signal line on the substrate, and the 2j-th reference output line is electrically connected with the 2j-th reference signal line.

In an exemplary embodiment, the distances between the boundaries of the third connection signal line, the fourth connection signal line, the sixth connection signal line, the seventh connection signal line and the (2j−1)-th first scan output line close to the display region and the display region are substantially equal.

In an exemplary embodiment, the drive circuit layer further includes: a first signal connection line located in the first conductive layer, the first signal connection line extends in the second direction and electrically connected with the (2j−1)-th third scan signal line and the 2j-th third scan signal line, respectively; an orthographic projection of the first signal connection line on the substrate at least partially overlaps an orthographic projection of the (2j−1)-th first scan output line, the j-th second scan output line and the j-th third scan output line on the substrate, and the first signal connection line is electrically connected with the j-th third scan output line.

In an exemplary embodiment, the (2j−1)-th second scan signal line includes: a first scan connection part and a second scan connection part connected with each other, the first scan connection part extends in the first direction, the second scan connection part extends in the second direction, and the j-th second scan output line includes: a first scan output connection part and a second scan output connection part connected with each other, the first scan output connection part extends in the first direction, the second scan output connection part extends in the second direction, and a virtual straight line extending in the second direction passes through the second scan connection part and the second scan output connection part, and the second scan connection part is located on a side of the first signal connection line close to the display region; an orthographic projection of the second scan connection part on the substrate at least partially overlaps an orthographic projection of the (2j−1)-th first scan output line and the first scan output connection part on the substrate, and the second scan connection part is electrically connected with the first scan output connection part; an orthographic projection of the first scan output connection part on the substrate at least partially overlaps an orthographic projection of the first signal connection line on the substrate; an orthographic projection of the second scan output connection part on the substrate at least partially overlaps an orthographic projection of the 2j-th third scan signal line and the 2j-th second scan signal line on the substrate, and the second scan output connection part is electrically connected with the 2j-th second scan signal line.

In an exemplary embodiment, the drive circuit layer further includes: a second signal connection line located in the first conductive layer, the second signal connection line extends in the first direction; an orthographic projection of the second signal connection line on the substrate at least partially overlaps an orthographic projection of the 2j-th first scan output line on the substrate, and the second signal connection line is electrically connected with the 2j-th first scan output line and the 2j-th first scan signal line, respectively, the length of the second signal connection line along the second direction is greater than the length of the first scan signal line along the second direction.

In an exemplary embodiment, the j-th light emitting output line includes: a first light emitting output connection part and a second light emitting output connection part connected with each other, the first light emitting output connection part extends in the first direction, the second light emitting output connection part extends in the second direction; the second light emitting output connection part is located on a side of the second scan output connection part close to the display region; an orthographic projection of the second light emitting output connection part on the substrate at least partially overlaps an orthographic projection of the second signal connection line, the (2j−1)-th light emitting signal line, the 2j-th light emitting signal line, the 2j-th third scan signal line and the 2j-th second scan signal line on the substrate, and the second light emitting output connection part is electrically connected with the (2j−1)-th light emitting signal line and the 2j-th light emitting signal line, respectively.

In an exemplary embodiment, the first signal lines electrically connected to the (2j−1)-th first scan signal line include the (2j−1)-th first scan output line, and the first signal lines electrically connected to the 2j-th first scan signal line include the 2j-th first scan output line and the second signal connection line; the second signal lines corresponding to the first signal lines electrically connected with the (2j−1)-th first scan signal line include the first signal connection line and the (2j−1)-th second scan signal line, and the second signal lines corresponding to the first signal lines electrically connected with the 2j-th first scan signal line include the j-th light emitting output line.

In an exemplary embodiment, an orthographic projection of the (2j−1)-th reference output line on the substrate at least partially overlaps an orthographic projection of the (2j−1)-th reference signal line on the substrate, and the (2j−1)-th reference output line is electrically connected with the (2j−1)-th reference signal line; an orthographic projection of the 2j-th reference output line on the substrate at least partially overlaps an orthographic projection of the 2j-th reference signal line on the substrate, and the 2j-th reference output line is electrically connected with the 2j-th reference signal line.

In an exemplary embodiment, the drive circuit layer further includes: a shielding layer located on a side of the first conductive layer adjacent to the substrate; the shielding layer at least includes a reference signal line.

In second aspect, the present disclosure further provides a display device including the display panel described above.

Other aspects may be understood upon reading and understanding the drawings and detailed description.

### BRIEF DESCRIPTION OF DRAWINGS

Accompanying drawings are used for providing understanding of technical solutions of the present disclosure, and form a part of the specification. They are used for explaining the technical solutions of the present disclosure together with embodiments of the present disclosure, but do not form a limitation on the technical solutions of the present disclosure.

FIG. 1 is a schematic diagram of a structure of a display apparatus.

FIG. 2 is a schematic diagram of a planar structure of a display panel.

FIG. 3 is a schematic diagram of an equivalent circuit of a pixel drive circuit.

FIG. 4 is a working timing diagram of a pixel drive circuit.

FIG. 5 is a schematic structural diagram I of a display panel in accordance with an embodiment of the present disclosure;

FIG. 6 is a schematic structural diagram II of a display panel in accordance with an embodiment of the present disclosure;

FIG. 7 is a schematic structural diagram III of a display panel in accordance with an embodiment of the present disclosure;

FIG. 8 is a schematic diagram of the display panel provided in FIGS. 5 to 7 after a pattern of a shielding layer is formed;

FIG. 9 is a schematic diagram of a pattern of a semiconductor layer of the display panel provided in FIGS. 5 to 7;

FIG. 10 is a schematic diagram of the display panel provided in FIGS. 5 to 7 after a pattern of a semiconductor layer is formed;

FIG. 11 is a schematic diagram of a pattern of a first conductive layer of the display panel provided in FIG. 5;

FIG. 12 is a schematic diagram of the display panel provided in FIG. 5 after a pattern of a first conductive layer is formed;

FIG. 13 is a schematic diagram of a pattern of a first conductive layer of the display panel provided in FIG. 6;

FIG. 14 is a schematic diagram of the display panel provided in FIG. 6 after a pattern of a first conductive layer is formed;

FIG. 15 is a schematic diagram of a pattern of a first conductive layer of the display panel provided in FIG. 7;

FIG. 16 is a schematic diagram of the display panel provided in FIG. 7 after a pattern of a first conductive layer is formed;

FIG. 17 is a schematic diagram of the display panel provided in FIG. 5 after a pattern of a third insulating layer is formed;

FIG. 18 is a schematic diagram of the display panel provided in FIG. 6 after a pattern of a third insulating layer is formed;

FIG. 19 is a schematic diagram of the display panel provided in FIG. 7 after a pattern of a third insulating layer is formed;

FIG. 20 is a schematic diagram of a pattern of a second conductive layer of the display panel provided in FIG. 5;

FIG. 21 is a schematic diagram of the display panel provided in FIG. 5 after a pattern of a second conductive layer is formed;

FIG. 22 is a schematic diagram of a pattern of a second conductive layer of the display panel provided in FIG. 6;

FIG. 23 is a schematic diagram of the display panel provided in FIG. 6 after a pattern of a second conductive layer is formed;

FIG. 24 is a schematic diagram of a pattern of a second conductive layer of the display panel provided in FIG. 7;

FIG. 25 is a schematic diagram of the display panel provided in FIG. 7 after a pattern of a second conductive layer is formed.

### DETAILED DESCRIPTION

To make objectives, technical solutions, and advantages of the present disclosure clearer, the embodiments of the present disclosure will be described in detail with reference to the accompanying drawings. It is to be noted that implementations may be practiced in a plurality of different forms. Those of ordinary skills in the art may easily understand such a fact that implementations and contents may be transformed into various forms without departing from the purpose and scope of the present disclosure. Therefore, the present disclosure should not be explained as being limited to contents described in following implementations only. The embodiments in the present disclosure and features in the embodiments may be combined randomly with each other if there is no conflict. In order to keep the following description of the examples of the present disclosure clear and concise, detailed descriptions of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display panel and a quantity of sub-pixels in each pixel are not limited to numbers shown in the drawings. The drawings described in the present disclosure are only schematic diagrams of the structures, an implementation mode in the present disclosure is not limited to the shape and value shown in the drawings.

Ordinal numerals such as “first”, “second”, and “third” in the specification are set to avoid confusion between constituent elements, but not to set a limit in quantity.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred device or element must have a particular orientation and be constructed and operated in the particular orientation. Therefore, they cannot be understood as limitations on the present disclosure. The positional relationships between the constituent elements may be changed as appropriate according to directions for describing the various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, a connection may be a fixed connection, or a detachable connection, or an integrated connection. It may be a mechanical connection or an electrical connection. It may be a direct mutual connection, or an indirect connection through middleware, or an internal communication between two elements. Those of ordinary skills in the art may understand specific meanings of these terms in the present disclosure according to specific situations.

In the specification, a transistor refers to an element which at least includes three terminals, i.e., a gate electrode, a drain electrode and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that, in the specification, the channel region refers to a region through which the current mainly flows.

In the specification, a first electrode may be a drain electrode, and a second electrode may be a source electrode. Or, the first electrode may be a source electrode, and the second electrode may be a drain electrode. In cases that transistors with opposite polarities are used, a current direction changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes a case that constituent elements are connected together through an element with a certain electrical effect. The “element with the certain electrical effect” is not particularly limited as long as electrical signals may be sent and received between the connected constituent elements. Examples of the “element with the certain electrical effect” not only include electrodes and wirings, but also include switch elements such as transistors, resistors, inductors, capacitors, other elements with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In this specification, “being disposed in a same layer” refers to a structure formed by patterning two (or more than two) structures through a same patterning process, and their materials may be the same or different. For example, materials of precursors forming multiple structures disposed in a same layer are the same, and resultant materials may be the same or different.

Triangle, rectangle, trapezoid, pentagon and hexagon in this specification are not strictly defined, and they may be approximate triangle, rectangle, trapezoid, pentagon or hexagon, etc.

There may be some small deformation caused by tolerance, and there may be chamfer, arc edge and deformation, etc.

In the present disclosure, “about” refers to that a boundary is defined not so strictly and numerical values within process and measurement error ranges are allowed.

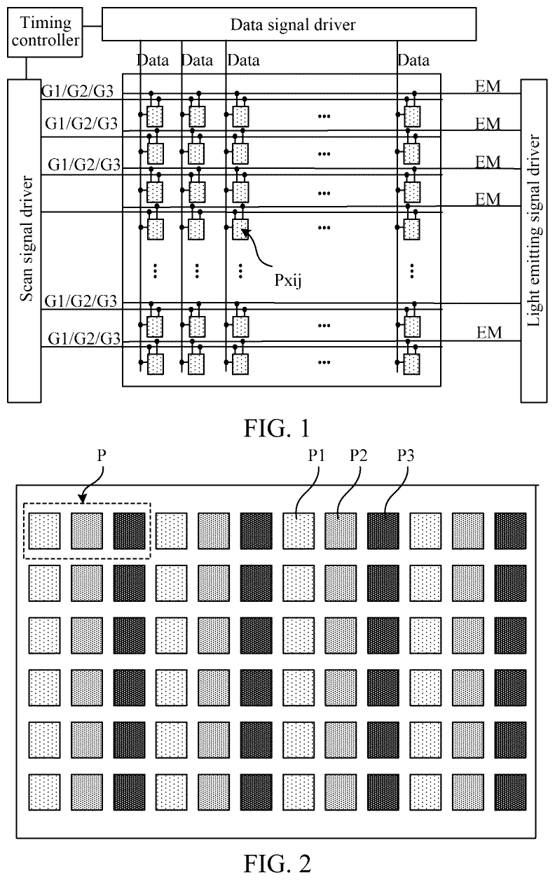

FIG. 1 is a schematic diagram of a structure of a display apparatus. As shown in FIG. 1, the display apparatus may include a timing controller, a data driver, a scan driver, a light emitting driver, and a pixel array, wherein the timing controller is connected with the data driver, the scan driver, and the light emitting driver, respectively, the data driver is respectively connected to a plurality of data signal lines Data, the scan driver is respectively connected to a plurality of first scan signal lines G1, a plurality of second scan signal lines G2 and a plurality of third scan signal lines G3, and the light emitting driver is respectively connected to a plurality of light emitting signal lines EM. The pixel array may include a plurality of sub-pixels Pxij, i and j may be natural numbers, at least one sub-pixel Pxij may include a circuit unit and a light emitting device connected with the circuit unit, and the circuit unit may include a pixel drive circuit which may be connected with the first scan signal line, the second scan signal line, the third scan signal line, the light emitting signal line and the data signal line, respectively. In an exemplary implementation, the timing controller may provide the data signal driver with a grayscale value and a control signal which are suitable for the specification of the data signal driver, provide the scan driver with a clock signal and a scan start signal which are suitable for the specification of the scan driver, and provide the light emitting driver with a clock signal and an emission stop signal which are suitable for the specification of the light emitting driver. The data driver may generate a data voltage to be provided to the data signal line Data using the gray-scale value and control signal received from the timing controller. For example, the data driver may sample the gray-scale value using the clock signal, and apply the data voltage corresponding to the gray-scale value to the data signal line by taking a pixel row as a unit. The scan driver may generate a scan signal to be provided to the first scan signal line, the second scan signal line, and the third scan signal line by receiving a clock signal, a scan start signal, or the like from the timing controller. For example the scan driver may provide a scan signal with an on-level pulse to the first scan signal line, the second scan signal line and the third scan signal line sequentially. For example, the scan driver may be constructed in a form of a shift register and may generate a scan signal by sequentially transmitting the scan start signal provided in a form of an on-level pulse to a next stage circuit under control of the clock signal. The light emitting driver may generate an emission signal to be provided to the light emitting signal line by receiving the clock signal, the emission stop signal, etc., from the timing controller. For example, the light emitting driver may provide an emission signal with an off-level pulse to the light emitting signal lines E1 to Eo sequentially. For example, the light emitting driver may be constructed in a form of the shift register and generate an emission signal by sequentially transmitting emission stop signals provided in the form of the off-level pulse to the next-stage circuit under the control of the clock signal.

FIG. 2 is a schematic diagram of a planar structure of a display panel. As shown in FIG. 2, the display panel may include a plurality of pixel units P arranged in a matrix, at least one of the plurality of pixel units P includes a first sub-pixel P1 emitting light of a first color, a second sub-pixel P2 emitting light of a second color, and a third sub-pixel P3 emitting light of a third color, the first sub-pixel P1, the second sub-pixel P2, and the third sub-pixel P3 each includes a pixel drive circuit and a light emitting device. Pixel drive circuits in the first sub-pixel P1, the second sub-pixel P2 and the third sub-pixel P3 are respectively connected with the first scan signal line, the second scan signal line, the third scan signal line, the data signal line and the light emitting signal line. The pixel drive circuit is configured to receive a data voltage transmitted by the data signal line and output corresponding current to the light emitting device under the control of the first scan signal line, the second scan signal line, the third scan signal line and the light emitting signal line. Light emitting devices in the first sub-pixel P1, the second sub-pixel P2, and the third sub-pixel P3 are respectively connected with a pixel drive circuit of a sub-pixel where the light emitting devices are located, and the light emitting device is configured to emit light with corresponding brightness in response to a current output by the pixel drive circuit of the sub-pixel where the light emitting device is located.

In an exemplary embodiment, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary embodiment, a sub-pixel may be in a shape of a rectangle, a rhombus, a pentagon, or a hexagon. Three sub-pixels may be arranged side by side horizontally, side by side vertically, or in a manner like a Chinese character “ [symbol] ”, the present disclosure is not limited thereto.

In an exemplary embodiment, the pixel unit may include four sub-pixels, which may be respectively a first sub-pixel to a fourth sub-pixel, and may be arranged side by side horizontally, side by side vertically, or in a square-shaped manner, which is not limited in the present disclosure.

In an exemplary embodiment, the first sub-pixel may be a red sub-pixel (R) emitting red light, the second sub-pixel may be a blue sub-pixel (B) emitting blue light, the third sub-pixel may be a green sub-pixel (G) emitting green light, and the fourth sub-pixel may be a white sub-pixel (W) emitting white light.

In an exemplary embodiment, the sub-pixels in the pixel unit may be in a shape of rectangular, rhombic, pentagonal, or hexagonal, and the present disclosure is not limited herein.

FIG. 3 is a schematic diagram of an equivalent circuit of a pixel drive circuit. In an exemplary embodiment, the pixel drive circuit may have a structure of 3T1C, 4T1C, 5T1C, 5T2C, 6T1C, 7T1C or 8T1C. As shown in FIG. 3, the pixel drive circuit may include five transistors (a first transistor T1 to a fifth transistor T5), one storage capacitor Cst, and may be electrically connected with eight signal lines (a data signal line Data, a first scan signal line G1, a second scan signal line G2, a third scan signal line G3, a light emitting signal line EM, a reference signal line REF, an initial signal line INIT, and a first power supply line VDD).

In an exemplary embodiment, as shown in FIG. 3, a control electrode of the first transistor T1 is electrically connected with the first scan signal line G1, a first electrode of the first transistor T1 is electrically connected with the data signal line Data, and a second electrode of the first transistor T1 is connected with a first node N1. The first transistor T1 may be referred to as a write transistor, transmits the data voltage of the data signal line to the first node N1 when the signal of the first scan signal line G1 is an active level signal.

In an exemplary embodiment, as shown in FIG. 3, a control electrode of the second transistor T2 is electrically connected with the second scan signal line G2, a first electrode of the second transistor T2 is electrically connected with the reference signal line REF, and a second electrode of the second transistor T2 is electrically connected with the first node N1. The second transistor T2 may be referred to as a compensation transistor, and when the signal of the second scan signal line G2 is an active level signal, the second transistor T2 transmits the signal of the reference signal line REF to the first node N1 to compensate the first node N1.

In an exemplary embodiment, as shown in FIG. 3, a control electrode of the third transistor T3 is electrically connected with the third scan signal line G3, a first electrode of the third transistor T3 is electrically connected with the initial signal line INIT, and a second electrode of the third transistor T3 is electrically connected with a third node N3. The third transistor T3 may be referred to as a reset transistor, and when the signal of the third scan signal line G3 is an active level signal, the third transistor T3 transmits the initial signal of the initial signal line INIT to the third node N3 to initialize or release the charge amount accumulated in a first electrode of a light emitting device L.

In an exemplary embodiment, as shown in FIG. 3, a control electrode of the fourth transistor T4 is electrically connected with the light emitting signal line EM, a first electrode of the fourth transistor T4 is electrically connected with the first power supply line VDD, and a second electrode of the fourth transistor T4 is electrically connected with a second node N2. The fourth transistor T4 may be referred to as a light emitting transistor. When the signal of the light emitting signal line EM is an active level signal, the fourth transistor T4 causes the light emitting device to emit light by forming a driving current path between the first power supply line VDD and a second power supply line VSS.

In an exemplary embodiment, as shown in FIG. 3, a control electrode of the fifth transistor T5 is electrically connected with the first Node N1, a first electrode of the fifth transistor T5 is electrically connected with the second node N2, and a second electrode of the fifth transistor T5 is electrically connected with the third Node N3. The fifth transistor T5 may be referred to as a drive transistor, and the fifth transistor T5 determines a magnitude of a driving current flowing between the first power supply line VDD and the second power supply line VSS according to a potential difference between the control electrode and the first electrode of the fifth transistor T5.

In an exemplary embodiment, a first terminal of the storage capacitor Cst is connected with the first node N1, and a second terminal of the storage capacitor Cst is connected with the third node N3, i.e., the first terminal of the storage capacitor Cst is connected with the control electrode of the fifth transistor T5. The storage capacitor Cst is configured to store the voltage value of the signal of the control electrode of the fifth transistor.

In an exemplary embodiment, as shown in FIG. 3, a first electrode of the light emitting device L is electrically connected with the third node N3, and a second electrode of the light emitting device L is connected with the second power supply line VSS.

In an exemplary embodiment, the first power supply line VDD continuously provides a high-level signal, the second power supply line VSS continuously provides a low-level signal, and the reference signal line REF and the initial signal line INIT provide a constant voltage signal, the voltage value of the initial signal line INIT is smaller than the voltage value of the second power supply line VSS.

Distinguished by their characteristics, transistors may be divided into N-type transistors and P-type transistors. When the transistor is a P type transistor, its turn-on voltage is a low-level voltage (e.g., 0V, −5V, −10V or other suitable voltages) and its turn-off voltage is a high-level voltage (e.g., 5V, 10V or other suitable voltages). When the transistor is an N type transistor, its turn-on voltage is a high-level voltage (e.g., 5V, 10V or other suitable voltages) and its turn-off voltage is a low-level voltage (e.g., 0V, −5V, −0V or other suitable voltages).

In an exemplary embodiment, the first transistor T1 to the fifth transistor T5 may be P-type transistors, or may be N-type transistors. Use of the same type of transistors in the pixel drive circuit may simplify a process flow, reduce the process difficulty of a display panel, and improve the product yield. In some possible implementations, the first transistor T1 to the fifth transistor T5 may include P type transistors and N type transistors.

In an exemplary embodiment, the storage capacitor Cst may be a capacitor device manufactured by a process, for example, a capacitor device implemented by manufacturing specialized capacitor electrodes, and a plurality of capacitor electrodes of the capacitor may be manufactured by a metal layer, a semiconductor layer (e.g. doped polysilicon) or the like. Alternatively, the storage capacitor Cst may be a parasitic capacitance between a plurality of devices and may be achieved by the transistor itself and other devices or lines. The connection mode of the storage capacitor Cst includes but is not limited to the mode described above and may be other suitable connection modes as long as the level of the corresponding node can be stored. The illustrative embodiments of the present disclosure are not limited thereto.

In an exemplary embodiment, for the first transistor T1 to the fifth transistor T5, low temperature poly silicon thin film transistors may be adopted, or oxide thin film transistors may be adopted, or both of a low temperature poly silicon thin film transistor and an oxide thin film transistor may be adopted. An active layer of a low temperature poly-silicon thin film transistor may be made of Low Temperature Poly-Silicon (LTPS for short), and an active layer of an oxide thin film transistor may be made of an oxide semiconductor (Oxide). The low temperature poly-silicon thin film transistor has advantages such as high migration rate and fast charging. The oxide thin film transistor has advantages such as low drain current. The low temperature poly-silicon thin film transistor and the oxide thin film transistor are integrated on one display panel to form a Low Temperature Polycrystalline Oxide (LTPO for short) display panel, so that advantages of the low temperature poly-silicon thin film transistor and the oxide thin film transistor can be utilized, low-frequency drive can be realized, power consumption can be reduced, and display quality can be improved.

In an exemplary embodiment, the first scan signal line G1, the second scan signal line G2, the light emitting signal line EM, the reference signal line REF, and the initial signal line INIT may extend in the horizontal direction, and the first power supply line VDD and the data signal line Data may extend in the vertical direction.

In an exemplary embodiment, the light emitting device L may include any one of an organic light emitting diode OLED, a quantum dot light emitting diode and an inorganic light emitting diode. For example, the light emitting device L may employ a micron-scale light emitting device, such as a Micro Light emitting Diode (Micro LED), a Mini Light emitting Diode (Mini LED), a Micro Organic Light Emitting Diode (Micro OLED), and the like, which are not limited by the embodiments of the present disclosure. For example, taking a case in which the light emitting device L is an organic electroluminescent diode (OLED) as an example, the light emitting device may include a first electrode (for example, as an anode), an organic light emitting layer, and a second electrode (for example, as a cathode) which are stacked.

In an exemplary embodiment, the display panel of the present disclosure may be applied to a display apparatus having a pixel drive circuit, such as an OLED, a quantum dot display (QLED), a light emitting diode display (Micro LED or Mini LED) or a quantum dot light emitting diode display (QDLED), etc., which is not limited here in the present disclosure.

In an exemplary implementation, the organic emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary embodiment, one or more of hole injection layers, hole transport layers, electron block layers, hole block layers, electron transport layers and electron injection layers of all sub-pixels may be connected together to form a common layer. The light emitting layers of adjacent sub-pixels may overlap slightly with each other, or may be isolated from each other.

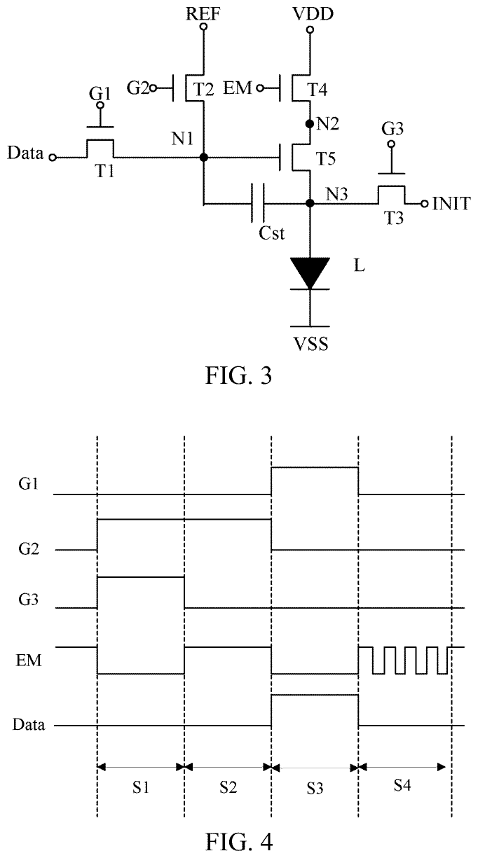

FIG. 4 is a working timing diagram of a pixel drive circuit. An exemplary embodiment of the present disclosure will be described below through a working process of the pixel drive circuit exemplified in FIG. 3. The pixel drive circuit in FIG. 3 includes five transistors (a first transistor T1 to a fifth transistor T5) and one storage capacitor Cst, and the five transistors are all N-type transistors.

In an exemplary embodiment, as shown in FIGS. 3 and 4, the working process of the pixel drive circuit may include following operations.

In a first stage S1, referred to as a reset stage, the signals of the second scan signal line G2 and the third scan signal line G3 are high-level signals, and the signals of the first scan signal line G1 and the light emitting signal line EM are low-level signals. The signal of the second scan signal line G2 is a high-level signal, the second transistor T2 is turned on, the reference signal of the reference signal line REF is written to the first node N1 to initialize (reset) the storage capacitor Cst, and clear the original charge in the storage capacitor Cst. At this time, the voltage value V_{N1} of the first node N1 meets V_{N1}=Vref, and Vref is the voltage value of the reference signal, the signal of the third scan signal line G3 is a high-level signal, the third transistor T3 is turned on, and the initial signal of the initial signal line INIT is written to the third node N3 to initialize (reset) the first electrode of the light emitting device L and empty the pre-stored voltage inside it and complete the initialization. At this time, the voltage value of the third node N3 satisfies V_{N3}=Vinit. The signals of the first scan signal line G1 and the light emitting signal line EM are low-level signals, and the first transistor T1 and the fourth transistor T4 are turned off. At this stage, the light emitting device L does not emit light.

In a second stage S2, referred to as a threshold compensation stage, the signals of the second scan signal line G2 and the light emitting signal line EM are high-level signals, and the signals of the first scan signal line G1 and the third scan signal line G3 are low-level signals. The signal of the second scan signal line G2 is a high-level signal, the second transistor T2 is continuously turned on, the reference signal of the reference signal line REF is written to the first node N1 to initialize (reset) the storage capacitor Cst, and clear the original charge in the storage capacitor Cst. At this time, the voltage value V_{N1} of the first node N1 meets V_{N1}=Vref, which is the voltage value of the reference signal, the signal of the light emitting signal line EM is a high-level signal, the fourth transistor T4 is turned on, and the signal of the first power supply line VDD charges the third node N3 through the turned-on fourth transistor T4, the second node N2 and the turned-on fifth transistor T5 until the voltage value of the third node N3 meets V_{N3}=Vref−Vth, Vth is the threshold voltage of the fifth transistor T5, at this time, the storage voltage value of the storage capacitor is Vth. The signals of the first scan signal line G1 and the third scan signal line G3 are low-level signals, and the first transistor T1 and the third transistor T3 are turned off. At this stage, the light emitting device L does not emit light.

In a third stage S3, referred to as a data writing stage, the signal of the first scan signal line G1 is a high-level signal, and the signals of the second scan signal line G2, the third scan signal line G3 and the light emitting signal line EM are low-level signals. The data signal line Data outputs a data voltage. At this stage, because the first terminal of the storage capacitor Cst is at a low level, the fifth transistor T5 is turned on, the signal of the first scan signal line G1 is a high-level signal, the first transistor T1 is turned on, and the data voltage output by the data signal line D is written to the first node N1. At this time, the voltage value V_{N1} of the first node N1 meets V_{N1}=Vdata, and Vdata is the voltage value of the data voltage. At this time, the third node N3 jumps under the action of the storage capacitor Cst, and the voltage value of the third node N3 meets V_{N3}=Vref−Vth+a (Vdata−Vref), and a is a fixed value. The signals of the second scan signal line G2, the third scan signal line G3 and the light emitting signal line EM are low-level signals, and the second transistor T2, the third transistor T3 and the fourth transistor T4 are turned off. At this stage, the light emitting device L does not emit light.

In a fourth stage S4, referred to as a light emitting stage, the signal of the light emitting signal line EM is a pulse signal, and the signals of the first scan signal line G1, the second scan signal line G2, and the third scan signal line G3 are low-level signals. When the signal of the light emitting signal line EM is an active level signal, the fourth transistor T4 is turned on, and the power supply voltage outputted from the first power supply line VDD provides a driving voltage to the first electrode of the light emitting device L through the turned-on fourth transistor T4, the second node N2, the turned-on fifth transistor T5 and the third node N3 to drive the light emitting device L to emit light.

In a drive process of the pixel drive circuit, a drive current flowing through the fifth transistor T5 (drive transistor) is determined by a voltage difference between the gate electrode and the first electrode of the third transistor T5. Because the voltage of the second node N2 is Vdata −Vth, the drive current of the fifth transistor T5 is:

$${I = K * {( Vgd - Vth )}^{2} = K * [ Vdata - Vref + Vth - a ( Vdata - Vref ) ) - Vth ]}^{2} = K * {[ ( 1 - a ) * ( Vdata - Vref ) ]}^{2}$$

Herein, I is a driving current flowing through the fifth transistor T5, that is, a driving current driving the light emitting device L, K is a constant, and Vgs is a voltage difference between the gate electrode and the first electrode of the fifth transistor T5.

It can be seen from the derivation results of the above current formula that in the light emitting stage, the drive current of the fifth transistor T5 is not affected by the threshold voltage of the fifth transistor T5, thereby eliminating an influence of the threshold voltage of the fifth transistor T5 on the drive current, ensuring the uniformity of the display brightness of the display product, and improving the display effect of the whole display product.

In an exemplary embodiment, the compensation time of the pixel drive circuit does not occupy the data writing time, so the compensation effect is not affected by the resolution and refresh frequency of the display panel.

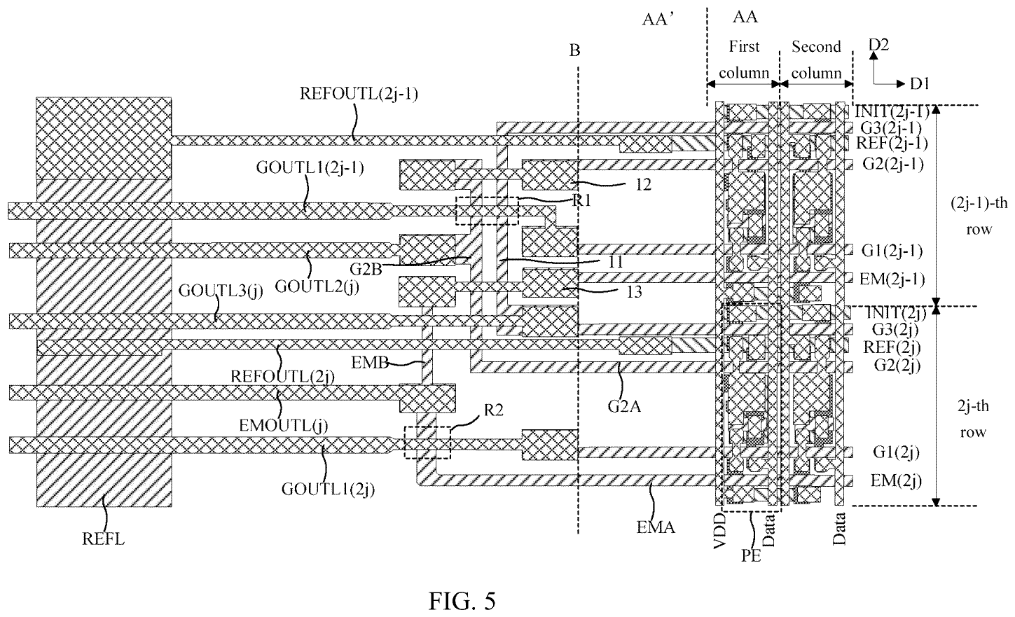

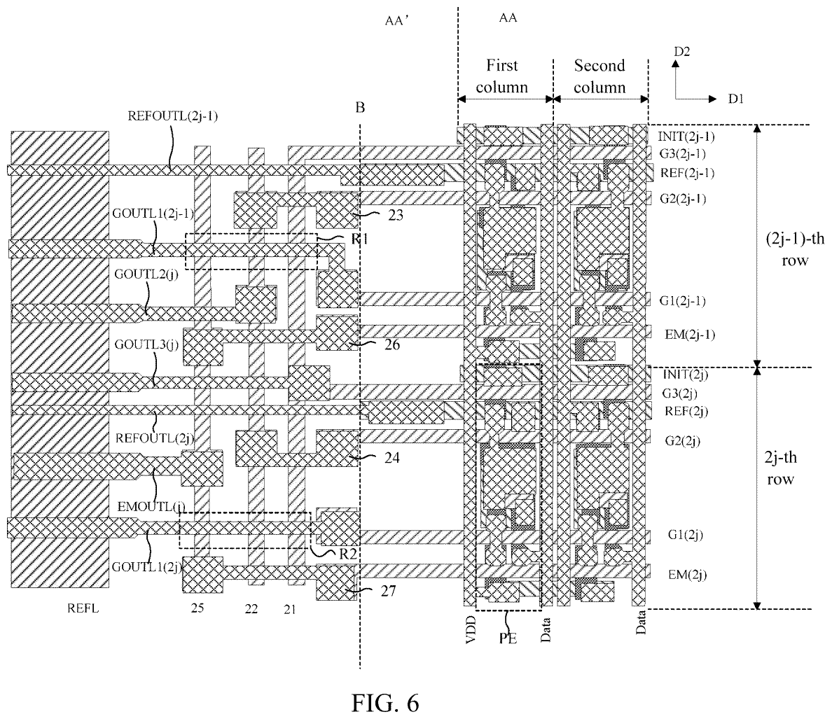

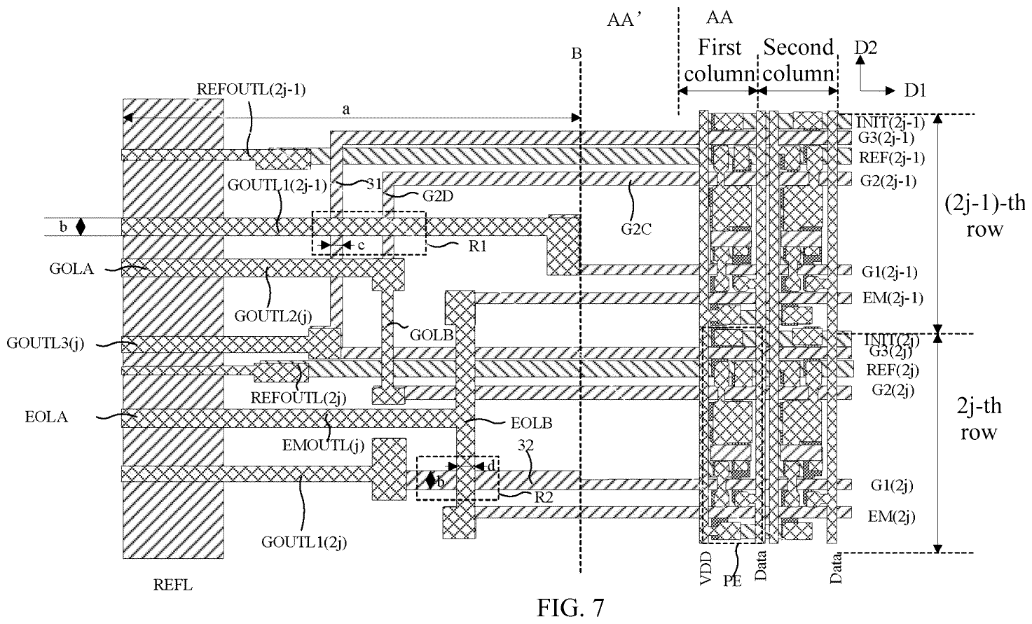

FIG. 5 is a schematic structural diagram I of a display panel in accordance with an embodiment of the present disclosure, FIG. 6 is a schematic structural diagram II of a display panel in accordance with an embodiment of the present disclosure, and FIG. 7 is a schematic structural diagram III of a display panel in accordance with an embodiment of the present disclosure. As shown in FIGS. 5 to 7, a display panel provided by an embodiment of the present disclosure may include a substrate including a display region AA and a non-display region AA′, and a drive circuit layer provided on the substrate including a plurality of pixel drive circuits PE provided in the display region AA and a plurality of first scan signal lines provided in the display region AA and the non-display region AA′, the first scan signal lines extend at least partially in a first direction D1, the pixel drive circuits PE are electrically connected with the first scan signal lines, and the first scan signal lines connected with adjacent rows of pixel drive circuits are electrically isolated from each other. In FIGS. 5 to 7, G1(2j−1) refers to a first scan signal line electrically connected with a (2j−1) th row of pixel drive circuits, and G1(2j) refers to a first scan signal line electrically connected with a 2j-th row of pixel drive circuits. FIGS. 5 to 7 are illustrated by taking two rows and two columns of pixel drive circuits in the display region as an example.

In an exemplary embodiment, the drive circuit layer may further include a first signal line located in the non-display region AA′ and a second signal line corresponding to the first signal line, the first signal line is electrically connected with the first scan signal line and configured to supply a signal to the first scan signal line, an orthographic projection of the first signal line on the substrate at least partially overlaps an orthographic projection of the corresponding second signal line on the substrate. As shown in FIGS. 5 to 7, R1 is an overlapping region of the first signal line electrically connected with the (2j−1)-th first scan signal line and the corresponding second signal line, and R2 is an overlapping region of the first signal line electrically connected with the 2j-th first scan signal line and the corresponding second signal line.

In an exemplary embodiment, the resistance R of the first signal lines electrically connected with adjacent first scan signal lines are substantially equal and/or the capacitance value C between the first signal lines electrically connected with adjacent first scan signal lines and the corresponding second signal lines are substantially equal. Herein, A and B are substantially equal means that A and B can be equal, or there can be a difference between A and B, but the difference is less than a threshold difference. A and B may denote a resistance of the first signal lines electrically connected with adjacent first scan signal lines or may denote a capacitance value between the first signal lines electrically connected with adjacent first scan signal lines and corresponding second signal lines. The threshold difference refers to a difference value that can make the difference in the display effect of the display panel unrecognizable to human eyes, and may be determined according to the configuration of the display panel, which is not limited here in the present disclosure.

In the present disclosure, the resistance of the first signal lines electrically connected with the adjacent first scan signal lines are substantially equal and/or the capacitance value between the first signal lines electrically connected with the adjacent first scan signal lines and the corresponding second signal lines are substantially equal, so that the RC difference of the first signal lines electrically connected with the adjacent first scan signal lines is reduced, the display abnormality is eliminated, and the display effect of the display panel can be improved.

In an exemplary embodiment, the substrate may be a rigid substrate or a flexible substrate, wherein the rigid substrate may be, but is not limited to, one or more of glass and metal foil; the flexible substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers.

In an exemplary embodiment, the flexible substrate may include a first flexible material layer, a first inorganic material layer, a semiconductor layer, a second flexible material layer, and a second inorganic material layer which are stacked. Materials of the first flexible material layer and second flexible material layer may be polyimide (PI), polyethylene terephthalate (PET), or a polymer soft film subjected to surface treatment, etc. Materials of the first inorganic material layer and second inorganic material layer may be silicon nitride (SiNx), silicon oxide (SiOx), or the like, so as to improve water-oxygen resistance capability of the substrate. The first inorganic material layer and second inorganic material layer are also referred to as barrier layers. A material of the semiconductor layer may be amorphous silicon (a-si). In an exemplary embodiment, taking a laminated structure of PI1/Barrier1/a-si/PI2/Barrier2 as an example, its preparation process may include: firstly, coating a layer of polyimide on the glass carrier plate, curing it into a film to form a first flexible (PI1) layer; then, depositing a layer of barrier thin film on the first flexible layer to form a first barrier (Barrier1) layer covering the first flexible layer; then depositing a layer of amorphous silicon thin film on the first barrier layer to form an amorphous silicon (a-si) layer covering the first barrier layer; then coating a layer of polyimide on the amorphous silicon layer, curing it into a film to form a second flexible (PI2) layer; then depositing a layer of barrier thin film on the second flexible layer to form a second barrier (Barrier2) layer covering the second flexible layer, thereby completing preparation of the substrate.

In an exemplary embodiment, the display panel may further include a light emitting structure layer disposed on a side of the drive circuit layer away from the substrate and an encapsulation structure layer disposed on a side of the light emitting structure layer away from the substrate. In an exemplary embodiment, the display panel may include other film layers, such as a touch structure layer, which is not limited in the present disclosure.

In an exemplary embodiment, the light emitting structure layer may include an anode, a pixel definition layer, an organic light emitting layer and a cathode. The anode is connected with a second electrode of the drive transistor through a via, the organic light emitting layer is connected with the anode, the cathode is connected with the organic light emitting layer, and the organic light emitting layer emits light of corresponding color under the drive of the anode and the cathode.

In an exemplary embodiment, the encapsulation structure layer may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is provided between the first encapsulation layer and the third encapsulation layer, and it may be ensured that external water vapor cannot enter the light emitting structure layer.

In an exemplary embodiment, the touch structure layer may include a first touch insulating layer disposed on the encapsulation structure layer, a first touch metal layer disposed on the first touch insulating layer, a second touch insulating layer covering the first touch metal layer, a second touch metal layer disposed on the second touch insulating layer, and a touch protective layer covering the second touch metal layer, the first touch metal layer may include a plurality of bridge electrodes, the second touch metal layer may include a plurality of first and second touch electrodes, and the first or second touch electrodes may be connected with the bridge electrodes through a via.

In an exemplary embodiment, as shown in FIGS. 5 to 7, the drive circuit layer further includes a plurality of second scan signal lines, a plurality of third scan signal lines, a plurality of light emitting signal lines and a plurality of reference signal lines provided in the display region AA and the non-display region AA′, and the pixel drive circuits PE are electrically connected with the second scan signal lines, the third scan signal lines, the light emitting signal lines and the reference signal lines respectively, the second scan signal lines, the third scan signal lines, the light emitting signal lines and the reference signal lines extend at least partially in the first direction D1. G2(i) in FIGS. 5 to 7 refers to the i-th second scan signal line, G3(i) refers to the i-th third scan signal line, EM(i) refers to the i-th light emitting signal line, and REF(i) refers to the i-th reference signal line.

In an exemplary embodiment, as shown in FIGS. 5 to 7, an i-th row of pixel drive circuits are electrically connected to an i-th first scan signal line, an i-th second scan signal line, an i-th third scan signal line, an i-th light emitting signal line, and an i-th reference signal line, respectively, 1≤i≤M, and M is the total number of rows of the pixel drive circuits. As an example, the (2j−1)-th row of pixel drive circuits are electrically connected with the (2j−1)-th first scan signal line G1(2j−1), the (2j−1)-th second scan signal line G2(2j−1), the (2j−1)-th third scan signal line G3(2j−1), the (2j−1)-th light emitting signal line EM(2j−1) and the (2j−1)-th reference signal line REF(2j−1), respectively, the 2j-th row of pixel drive circuits are electrically connected with the 2j-th first scan signal line G1(2j), the 2j-th second scan signal line G2(2j−1), the 2j-th third scan signal line G3(2j), the 2j-th light emitting signal line EM(2j) and the 2j-th reference signal line REF(2j), respectively.

In an exemplary embodiment, as shown in FIGS. 5 to 7, an i-th third scan signal line, an i-th reference signal line, an i-th second scan signal line, an i-th first scan signal line, and an i-th light emitting signal line are sequentially arranged along a second direction D2, the i-th third scan signal line is located on a side of the i-th reference signal line close to the (i−1)-th light emitting signal line, the i-th light emitting signal line is located on a side of the i-th first scan signal line close to the (i+1)-th third scan signal line, and the second direction D2 intersects with the first direction D1. By way of example, the (2j−1)-th third scan signal line G3(2j−1), the (2j−1)-th reference signal line REF(2j−1), the (2j−1)-th second scan signal line G2(2j−1), the (2j−1)-th first scan signal line G1(2j−1) and the (2j−1)-th light emitting signal line EM(2j−1) are arranged along the second direction D2, the (2j−1)-th third scan signal line G3(2j−1) is located on a side of the (2j−1)-th reference signal line REF(2j−1) close to the (2j−2)-th light emitting signal line EM(2j−2), and the (2j−1)-th light emitting signal line EM(2j−1) is located on a side of the (2j−1)-th first scan signal line G1(2j−1) close to the 2j-th third scan signal G3(2j).

In an exemplary embodiment, the second signal line may be electrically connected with at least one of the second scan signal line, the third scan signal line, and the light emitting signal line.

In an exemplary embodiment, as shown in FIGS. 5 to 7, the drive circuit layer may further include M initial signal lines at least partially located in the display region AA, the initial signal lines extend in the first direction. The i-th row of pixel drive circuits are electrically connected with the i-th initial signal line. As an example, the (2j−1)-th row of pixel drive circuits are electrically connected with the (2j−1)-th initial signal line INIT(2j−1), and the 2j-th row of pixel drive circuits are electrically connected with the 2j-th initial signal line INIT(2j).

In an exemplary embodiment, as shown in FIGS. 5 to 7, the i-th initial signal line is located on a side of the i-th third scan signal line away from the i-th reference signal line.

In an exemplary embodiment, as shown in FIGS. 5 to 7, the drive circuit layer may further include M first scan output lines, M/2 second scan output lines, M/2 third scan output lines, M reference output lines, and M/2 light emitting output lines located in the non-display region AA′, wherein the first scan output lines, the second scan output lines, the third scan output lines, the reference output lines, and the light emitting output lines extend at least partially along the first direction D1. GOUTL1(i) in FIGS. 5 to 7 refers to the i-th first scan output line, REFOUTL(i) refers to the i-th reference output line, GOUTL2(j) refers to the j-th second scan output line, GOUTL3(j) refers to the j-th third scan output line, EMOUTL(j) refers to the j-th light emitting output line.

In an exemplary embodiment, as shown in FIGS. 5 to 7, the i-th first scan output line GOUTL1(i) is electrically connected with the i-th first scan signal line G1(i), the i-th reference output line REFOUTL1(i) is electrically connected with the i-th reference signal line REF(i), the j-th second scan output line GOUTL2(j) is electrically connected with the (2j−1)-th second scan signal line G2(2j−1) and the 2j-th second scan signal line G2(2j), respectively, the j-th third scan output line GOUTL3(j) is electrically connected with the (2j−1)-th third scan signal line G3(2j−1) and the 2j-th third scan signal G3(2j), respectively, and the j-th light emitting output line EMOUTL(j) is electrically connected with the (2j−1)-th light emitting signal line EM(2j−1) and the 2j-th light emitting signal line EM(2j), respectively, 1≤j≤M/2. Exemplarily, a first first scan output line is electrically connected with a first first scan signal line, a second first scan output line is electrically connected with a second first scan signal line, and so on. A first reference output line is electrically connected with a first reference signal line, a second reference output line is electrically connected with a second reference signal line, and so on. A first second scan output line is electrically connected with a first second scan signal line and a second second scan signal line respectively, a second second scan output line is electrically connected with a third second scan signal line and a fourth second scan signal line respectively, and so on. A first third scan output line is electrically connected with a first third scan signal line and a second third scan signal line respectively, a second third scan output line is electrically connected with a third third scan signal line and a fourth third scan signal line respectively, and so on. A first light emitting output line is electrically connected with a first light emitting signal line and a second light emitting signal line respectively, a second light emitting output line is electrically connected with a third light emitting signal line and a fourth light emitting signal line respectively, and so on.

In an exemplary embodiment, a light emitting output line is connected with two light emitting signal lines, a second scan output line is connected with two second scan signal lines, and a third scan output line is connected with two third scan signal lines, thereby reducing the number of signal lines of the display panel and realizing a narrow bezel of the display panel.

In an exemplary embodiment, as shown in FIGS. 5 to 7, the (2j−1)-th reference output line REFOUTL1(2j−1), the (2j−1)-th first scan output line GOUTL1(2j−1), the j-th second scan output line GOUTL2(j), the j-th third scan output line GOUTL3(j), the 2j-th reference output line REFOUTL(2j), the j-th light emitting output line EMOUTL(j) and the 2j-th first scan output line GOUTL1(2j) are arranged sequentially along the second direction D2.

In an exemplary embodiment, as shown in FIGS. 5 to 7, the drive circuit layer may further include a reference power supply line REFL located in the non-display region AA′ and a data signal line Data and a first power supply line VDD located at least partially in the display region, the reference power supply line REFL, the data signal line Data and the first power supply line VDD extend at least partially in the second direction D2.

In an exemplary embodiment, the pixel drive circuit is electrically connected with the data signal line Data and the first power supply line VDD respectively.

In an exemplary embodiment, an orthographic projection of the reference power supply line REFL on the substrate at least partially overlaps an orthographic projection of the reference output line on the substrate, and the reference power supply line REFL is electrically connected with the reference output line.

In an exemplary embodiment, the drive circuit layer may include a first conductive layer and a second conductive layer sequentially stacked on the substrate.

The first conductive layer may at least include a first scan signal line, a second scan signal line, a third scan signal line, a light emitting signal line and a reference power supply line REFL; The second conductive layer may include at least a first scan output line, a second scan output line, a third scan output line, a reference output line, a light emitting output line, a data signal line Data, and a first power supply line VDD.

In an exemplary embodiment, the first conductive layer and the second conductive layer have substantially equal square resistance.

In an exemplary embodiment, the first conductive layer and the second conductive layer are made of the same material and thickness.

In an exemplary embodiment, the average lengths of the first scan output line, the second scan output line, the third scan output line, the reference output line, and the light emitting output line in the second direction may be substantially equal.

In an exemplary embodiment, the average lengths of the data signal line Data and the first power supply line VDD in the first direction are substantially equal.

In an exemplary embodiment, the distances between the boundaries B of the first signal lines electrically connected with adjacent first scan signal lines close to the display region and the display region are substantially equal, and the average lengths of the first signal lines electrically connected with adjacent first scan signal lines in the second direction are substantially equal. The distances between the boundaries of the first signal lines electrically connected to the adjacent first scan signal lines close to the display region and the display region are substantially equal, in the case of the same square resistance of the first conductive layer and the second conductive layer, the resistance of the first signal lines electrically connected with adjacent first scan signal lines can be made equal.

In an exemplary embodiment, areas of an overlapping region between the first signal lines electrically connected to the adjacent first scan signal lines and corresponding second signal lines are substantially equal. Areas of an overlapping region between the first signal lines electrically connected to the adjacent first scan signal lines and corresponding second signal lines are substantially equal, in the case of the same square resistance of the first conductive layer and the second conductive layer, the resistance of the first signal lines electrically connected with adjacent first scan signal lines can be made equal.

In an exemplary embodiment, as shown in FIG. 5, the drive circuit layer may further include a first signal connection line 11 located in the first conductive layer. The first signal connection line 11 may extend in the second direction D2 and is electrically connected with the (2j−1)-th third scan signal line G3(2j−1) and the 2j-th third scan signal line G3(2j), respectively.

In an exemplary embodiment, the first signal connection line 11 may be integrally structured with the (2j−1)-th third scan signal line G3(2j−1) and the 2j-th third scan signal line G3(2j).

In an exemplary embodiment, as shown in FIG. 5, an orthographic projection of the first signal connection line 11 on the substrate at least partially overlaps an orthographic projection of the (2j−1)-th first scan output line GOUTL1(2j−1) on the substrate.

In an exemplary embodiment, the length of the first signal connection line 11 in the first direction may be substantially equal to the length of the third scan signal line in the second direction.

In an exemplary embodiment, as shown in FIG. 5, an orthographic projection of the j-th third scan output line GOUTL3(j) on the substrate at least partially overlaps an orthographic projection of the 2j-th third scan signal line G3(2j) on the substrate, and the j-th third scan output line GOUTL3(j) is electrically connected with the 2j-th third scan signal line G3(2j). In an exemplary embodiment, the j-th third scan output line GOUTL3(j) is electrically connected with the (2j−1)-th third scan signal line G3(2j−1) through the 2j-th third scan signal line G3(2j) and the first signal connection line 11.

In an exemplary embodiment, as shown in FIG. 5, the drive circuit layer may further include a second signal connection line 12 located in the second conductive layer which may extend in the first direction D1.

In an exemplary embodiment, as shown in FIG. 5, the 2j-th second scan signal line G2(2j) may include a first scan connection part G2A and a second scan connection part G2B connected with each other. The first scan connection part G2A extends in the first direction D1, the second scan connection part G2B extends in the second direction D2, and the first signal connection line 11 may be located on a side of the second scan connection part G2B close to the display region AA.

In an exemplary embodiment, as shown in FIG. 5, an orthographic projection of the second scan connection part G2B on the substrate at least partially overlaps an orthographic projection of the (2j−1)-th first scan output line GOUTL1(2j−1), the j-th second scan output line GOUTL2(j), the j-th third scan output line GOUTL3(j) and the second signal connection line 12 on the substrate, and the second scan connection part G2B is electrically connected with the j-th second scan output line GOUTL2(j) and the second signal connection line 12, respectively.

In an exemplary embodiment, as shown in FIG. 5, an orthographic projection of the second signal connection line 12 on the substrate at least partially overlaps an orthographic projection of the (2j−1)-th second scan signal line G2(2j−1) and the first signal connection line 11 on the substrate, and the second signal connection line 12 is electrically connected with the (2j−1)-th second scan signal line G2(2j−1).

In an exemplary embodiment, as shown in FIG. 5, the drive circuit layer may further include a third signal connection line 13 located in the second conductive layer, the third signal connection line 13 extends in the first direction D1.

In an exemplary embodiment, as shown in FIG. 5, the distances between the boundaries of the second signal connection line 12 and the third signal connection line 13 close to the display region and the boundaries of the display region may be substantially equal, and may be substantially equal to the distance between the boundary B of the (2j−1)-th second scan signal line G2(2j−1) close to the display region and the boundary of the display region.

In an exemplary embodiment, as shown in FIG. 5, the distances between the boundaries of the second and third signal connection lines 12 and 13 away from the display region and the boundaries of the display region may be substantially equal.

In an exemplary embodiment, as shown in FIG. 5, the average length of the second signal connection line 12 in the second direction may be substantially equal to the average length of the third signal connection line 13 in the second direction.

In an exemplary embodiment, as shown in FIG. 5, the 2j-th light emitting signal line EM(2j) may include a first light emitting connection part EMA extending in the first direction D1 and a second light emitting connection part EMB extending in the second direction D2, which are connected with each other, and the second light emitting connection part EMB is located between the reference power supply line REFL and the second scan connection part G2B.

In an exemplary embodiment, as shown in FIG. 5, an orthographic projection of the second light emitting connection part EMB on the substrate at least partially overlaps orthographic projections of the j-th light emitting output line EMOUTL(j), the j-th third scan output line GOUTL3(j), the 2j-th first scan output line GOUTL1(2j) and the third signal connection line 13 on the substrate, and the second light emitting connection part EMB is electrically connected with the j-th light emitting output line EMOUTL(j) and the third signal connection line 13, respectively.

In an exemplary embodiment, as shown in FIG. 5, an orthographic projection of the third signal connection line 13 on the substrate at least partially overlaps orthographic projections of the (2j−1)-th light emitting signal line EM(2j−1), the first signal connection line 11 and the second scan connection part G2B on the substrate, and the third signal connection line 13 is electrically connected with the (2j−1)-th light emitting signal line EM(2j−1). The j-th light emitting output line EMOUTL(j) is electrically connected with the (2j−1)-th light emitting signal line EM(2j−1) through the second light emitting connection part EMB and the third signal connection line 13.

In an exemplary embodiment, the length in the first direction of the overlapping region of the second light emitting connection part and the 2j-th first scan output line is greater than the length in the second direction of the first light emitting connection part.

In an exemplary embodiment, as shown in FIG. 5, the first signal lines electrically connected with the i-th first scan signal line include the i-th first scan output line, that is, the first signal lines electrically connected with the (2j−1)-th first scan signal line G1(2j−1) may include the (2j−1)-th first scan output line GOUTL1(2j−1), and the first signal lines electrically connected with the 2j-th first scan signal line G1(2j) may include the 2j-th first scan output line GOUTL1(2j).

In an exemplary embodiment, as shown in FIG. 5, the second signal lines corresponding to the first signal lines electrically connected with the (2j−1)-th first scan signal line G1(2j−1) may include the first signal connection line 11 and the 2j-th second scan signal line G2(2j).

In an exemplary embodiment, as shown in FIG. 5, the second signal lines corresponding to the first signal lines electrically connected with the 2j-th first scan signal line G1(2j) may include the 2j-th light emitting signal line EM(2j).

In an exemplary embodiment, as shown in FIG. 5, an orthographic projection of the (2j−1)-th reference output line REFOUTL(2j−1) on the substrate at least partially overlaps orthographic projections of the first signal connection line 11 and the (2j−1)-th reference signal line REF(2j−1) on the substrate, and the (2j−1)-th reference output line REFOUTL(2j−1) is electrically connected with the (2j−1)-th reference signal line REF(2j−1).

In an exemplary embodiment, as shown in FIG. 5, an orthographic projection of the 2j-th reference output line REFOUTL(2j) on the substrate at least partially overlaps orthographic projections of the second scan connection part G2B, the second light emitting connection part EMB and the 2j-th reference signal line REF(2j) on the substrate, and the 2j-th reference output line REFOUTL(2j) is electrically connected with the 2j-th reference output line REFOUTL(2j).

In an exemplary embodiment, as shown in FIG. 6, the drive circuit layer may further include a first signal connection line 21 located in the first conductive layer. The first signal connection line 21 may extend in the second direction D2 and is electrically connected with the (2j−1)-th third scan signal line G3(2j−1) and the 2j-th third scan signal line G3(2j), respectively.

In an exemplary embodiment, as shown in FIG. 6, an orthographic projection of the first signal connection line 21 on the substrate at least partially overlaps orthographic projections of the (2j−1)-th first scan output line GOUTL1(2j−1) and the 2j-th first scan output line GOUTL1(2j) on the substrate.

In an exemplary embodiment, as shown in FIG. 6, an orthographic projection of the j-th third scan output line GOUTL3(j) on the substrate at least partially overlaps an orthographic projection of the 2j-th third scan signal line G3(2j) on the substrate, and the j-th third scan output line GOUTL3(j) is electrically connected with the 2j-th third scan signal line G3(2j). The j-th third scan output line GOUTL3( ) is electrically connected with the (2j−1)-th third scan signal line G3(2j−1) through the 2j-th third scan signal line G3(2j) and the first signal connection line.

In an exemplary embodiment, as shown in FIG. 6, the drive circuit layer may further include a second signal connection line 22 located in the first conductive layer and a third signal connection line 23 and a fourth signal connection line 24 located in the second conductive layer. The second signal connection line 22 extends in the second direction D2, the third signal connection line 23 and the fourth signal connection line 24 extend at least partially in the first direction D1, and the second signal connection line 22 is located on a side of the first signal connection line 21 away from the display region.

In an exemplary embodiment, as shown in FIG. 6, an orthographic projection of the second signal connection line 22 on the substrate at least partially overlaps orthographic projections of the (2j−1)-th first scan output line GOUTL1(2j−1), the 2j-th first scan output line GOUTL1(2j), the j-th second scan output line GOUTL2(j), the j-th third scan output line GOUTL3(j), the third signal connection line 23 and the fourth signal connection line 24 on the substrate, and the second signal connection line 22 is electrically connected with the j-th second scan output line GOUTL2(j), the third signal connection line 23 and the fourth signal connection line 24, respectively.

In an exemplary embodiment, as shown in FIG. 6, an orthographic projection of the third signal connection line 23 on the substrate at least partially overlaps orthographic projections of the first signal connection line 21 and the (2j−1)-th second scan signal line G2(2j−1) on the substrate, and the third signal connection line 23 is electrically connected with the (2j−1)-th second scan signal line G2(2j−1). The j-th second scan output line GOUTL2(j) is electrically connected with the (2j−1)-th second scan signal line G2(2j−1) through the second signal connection line 22 and the third signal connection line 23.

In an exemplary embodiment, as shown in FIG. 6, an orthographic projection of the fourth signal connection line 24 on the substrate at least partially overlaps orthographic projections of the first signal connection line 21 and the 2j-th second scan signal line G2(2j) on the substrate, and the fourth signal connection line 24 is electrically connected with the 2j-th second scan signal line G2(2j). The j-th second scan output line GOUTL2(j) is electrically connected with the (2j−1)-th second scan signal line G2(2j) through the second signal connection line 22 and the fourth signal connection line 24.

In an exemplary embodiment, as shown in FIG. 6, the drive circuit layer may further include a fifth signal connection line 25 located in the first conductive layer and a sixth signal connection line 26 and a seventh signal connection line 27 located in the second conductive layer. Herein, the fifth signal connection line 25 may extend in the second direction D2, the sixth signal connection line 26 and the seventh signal connection line 27 may extend at least partially in the first direction D1, and the fifth signal connection line 25 may be located on a side of the second signal connection line 22 away from the display region.

In an exemplary embodiment, as shown in FIG. 6, an orthographic projection of the fifth signal connection line 25 on the substrate at least partially overlaps orthographic projections of the (2j−1)-th first scan output line GOUTL1(2j−1), the 2j-th first scan output line GOUTL1(2j), the j-th second scan output line GOUTL2(j), the j-th third scan output line GOUTL3(j), the j-th light emitting output line EMOUTL(j), the sixth signal connection line 26 and the seventh signal connection line 27 on the substrate, and the fifth signal connection line 25 is electrically connected with the j-th light emitting output line EMOUTL(j), the sixth signal connection line 26 and the seventh signal connection line 27, respectively.

In an exemplary embodiment, as shown in FIG. 6, an orthographic projection of the sixth signal connection line 26 on the substrate at least partially overlaps orthographic projections of the first signal connection line 21, the second signal connection line 22 and the (2j−1)-th light emitting signal line EM(2j−1) on the substrate, and the sixth signal connection line 26 is electrically connected with the (2j−1)-th light emitting signal line EM(2j−1).

In an exemplary embodiment, as shown in FIG. 6, an orthographic projection of the seventh signal connection line 27 on the substrate at least partially overlaps orthographic projections of the first signal connection line 21, the second signal connection line 22 and the 2j-th light emitting signal line EM(2j) on the substrate, and the seventh signal connection line 27 is electrically connected with the 2j-th light emitting signal line EM(2j).

In an exemplary embodiment, as shown in FIG. 6, the first signal lines electrically connected with the i-th first scan signal line include the i-th first scan output line, i.e. the first signal lines electrically connected with the (2j−1)-th first scan signal line G1(2j−1) include the (2j−1)-th first scan output line GOUTL1(2j−1), and the first signal lines electrically connected with the 2j-th first scan signal line G1(2j) include the 2j-th first scan output line GOUTL1(2j).

In an exemplary embodiment, as shown in FIG. 6, the second signal lines corresponding to the first signal lines electrically connected with the (2j−1)-th first scan signal line may include the first signal connection line 21, the second signal connection line 22, and the fifth signal connection line 25.

In an exemplary embodiment, as shown in FIG. 6, the second signal lines corresponding to the first signal lines electrically connected with the 2j-th first scan signal line G1(2j) may include the first signal connection line 21, the second signal connection line 22, and the fifth signal connection line 25.

In an exemplary embodiment, the length of the first signal connection line 21 in the first direction D1, the length of the second signal connection line 22 in the first direction D1, and the length of the fifth signal connection line 25 in the first direction D1 may be substantially equal or may not be equal, which is not limited here in the present disclosure.

In an exemplary embodiment, the distance between the boundary of the third signal connection line 23 close to the display region and the display region may be substantially equal to the distance between the boundary B of the (2j−1)-th first scan output line GOUTL1(2j−1) close to the display region and the display region.

In an exemplary embodiment, the distance between the boundary of the fourth signal connection line 24 close to the display region and the display region may be substantially equal to the distance between the boundary B of the (2j−1)-th first scan output line GOUTL1(2j−1) close to the display region and the display region.

In an exemplary embodiment, the length of the third signal connection line 23 in the first direction D1 may be substantially equal to the length of the fourth signal connection line 24 in the first direction D1.

In an exemplary embodiment, the distance between the boundary of the sixth signal connection line 26 close to the display region and the display region may be substantially equal to the distance between the boundary B of the (2j−1)-th first scan output line GOUTL1(2j−1) close to the display region and the display region.

In an exemplary embodiment, the distance between the edge of the seventh signal connection line 27 close to the display region and the display region may be substantially equal to the distance between the edge B of the (2j−1)-th first scan output line GOUTL1(2j−1) close to the display region and the display region.

In an exemplary embodiment, the length of the sixth signal connection line 26 in the first direction D1 may be substantially equal to the length of the seventh signal connection line 27 in the first direction D1 and greater than the length of the third signal connection line 23 in the first direction D1.

In an exemplary embodiment, as shown in FIG. 6, an orthographic projection of the (2j−1)-th reference output line REFOUTL(2j−1) on the substrate at least partially overlaps orthographic projections of the first signal connection line 21, the second signal connection line 22, the fifth signal connection line 25 and the (2j−1)-th reference signal line REF(2j−1) on the substrate, and the (2j−1)-th reference output line REFOUTL(2j−1) is electrically connected with the (2j−1)-th reference signal line REF(2j−1).

In an exemplary embodiment, as shown in FIG. 6, an orthographic projection of the 2j-th reference output line REFOUTL(2j) on the substrate at least partially overlaps orthographic projections of the first signal connection line 21, the second signal connection line 22, the fifth signal connection line 25 and the 2j-th reference signal line REF(2j) on the substrate, and the 2j-th reference output line REFOUTL(2j) is electrically connected with the 2j-th reference output line REFOUTL(2j).

In an exemplary embodiment, as shown in FIG. 7, the drive circuit layer may further include a first signal connection line 31 located in the first conductive layer. The first signal connection line 31 may extend in the second direction D2 and is electrically connected with the (2j−1)-th third scan signal line G3(2j−1) and the 2j-th third scan signal line G3(2j), respectively.

In an exemplary embodiment, as shown in FIG. 7, an orthographic projection of the first signal connection line 31 on the substrate at least partially overlaps orthographic projections of the (2j−1)-th first scan output line GOUTL1(2j−1), the j-th second scan output line GOUTL2(j), and the j-th third scan output line GOUTL3(j) on the substrate, and the first signal connection line 31 is electrically connected with the j-th third scan output line GOUTL3(j). The j-th third scan output line GOUTL3(j) is electrically connected with the (2j−1)-th third scan signal line G3(2j−1) and the 2j-th third scan signal line G3(2j) through the first signal connection line 31, respectively.

In an exemplary embodiment, as shown in FIG. 7, the length of the first signal connection line 31 in the first direction may be substantially equal to the length of the third scan signal line in the second direction.

In an exemplary embodiment, as shown in FIG. 7, the (2j−1)-th second scan signal line G2(2j−1) includes a first scan connection part G2C extending in the first direction D1 and a second scan connection part G2D extending in the second direction D2, which are connected with each other.

In an exemplary embodiment, as shown in FIG. 7, the j-th second scan output line GOUTL2(j) includes a first scan output connection part GOLA extending in the first direction D1 and a second scan output connection part GOLB extending in the second direction D2, which are connected with each other.

In an exemplary embodiment, as shown in FIG. 7, a virtual straight line extending in the second direction D2 passes through the second scan connection part G2D and the second scan output connection part GOLB, the second scan connection part G2D is located on a side of the first signal connection line 31 close to the display region AA.

In an exemplary embodiment, as shown in FIG. 7, an orthographic projection of the second scan connection part G2D on the substrate at least partially overlaps orthographic projections of the (2j−1)-th first scan output line GOUTL1(2j−1) and the first scan output connection part GOLA on the substrate, and the second scan connection part G2D is electrically connected with the first scan output connection part GOLA.

In an exemplary embodiment, as shown in FIG. 7, an orthographic projection of the first scan output connection part GOLA on the substrate at least partially overlaps an orthographic projection of the first signal connection line 31 on the substrate.

In an exemplary embodiment, as shown in FIG. 7, an orthographic projection of the second scan output connection part GOLB on the substrate at least partially overlaps orthographic projections of the 2j-th third scan signal line G3(2j) and the 2j-th second scan signal line G2(2j) on the substrate, and the second scan output connection part GOLB is electrically connected with the 2j-th second scan signal line G2(2j).

In an exemplary embodiment, as shown in FIG. 7, the drive circuit layer further includes a second signal connection line 32 located in the first conductive layer, the second signal connection line 32 extends in the first direction D1.

In an exemplary embodiment, as shown in FIG. 7, an orthographic projection of the second signal connection line 32 on the substrate at least partially overlaps an orthographic projection of the 2j-th first scan output line GOUTL1(2j) on the substrate, and the second signal connection line 32 is electrically connected with the 2j-th first scan output line GOUTL1(2j) and the 2j-th first scan signal line G1(2j), respectively.

In an exemplary embodiment, as shown in FIG. 7, the length of the second signal connection line 32 in the second direction D2 is greater than the length of the first scan signal line in the second direction D2.

In an exemplary embodiment, as shown in FIG. 7, the j-th light emitting output line EMOUTL(j) includes a first light emitting output connection part EOLA and a second light emitting output connection part EOLB connected with each other, the first light emitting output connection part EOLA extends in the first direction D1 and the second light emitting output connection part EOLB extends in the second direction D2; the second light emitting output connection part EOLB is located on a side of the second scan output connection part GOLB close to the display region AA.

In an exemplary embodiment, as shown in FIG. 7, an orthographic projection of the second light emitting output connection part EOLB on the substrate at least partially overlaps orthographic projections of the second signal connection line 32, the (2j−1)-th light emitting signal line EM(2j−1), the 2j-th light emitting signal line EM(2j), the 2j-th third scan signal line G3(2j) and the 2j-th second scan signal line G2(2j) on the substrate, and the second light emitting output connection part EOLB is electrically connected with the (2j−1)-th light emitting signal line EM(2j−1) and the 2j-th light emitting signal line EM(2j), respectively.

In an exemplary embodiment, as shown in FIG. 7, the first signal lines electrically connected with the (2j−1)-th first scan signal line G1(2j−1) may include the (2j−1)-th first scan output line GOUTL1(2j−1).

In an exemplary embodiment, as shown in FIG. 7, the first signal lines electrically connected with the 2j-th first scan signal line G1(2j) may include the 2j-th first scan output line GOUTL1(2j) and the second signal connection line 32.

In an exemplary embodiment, as shown in FIG. 7, the second signal lines corresponding to the first signal lines electrically connected with the (2j−1)-th first scan signal line may include the first signal connection line 31 and the (2j−1)-th second scan signal line G2(2j−1).

In an exemplary embodiment, as shown in FIG. 7, the second signal lines corresponding to the first signal lines electrically connected with the 2j-th first scan signal line G1(2j) may include the j-th light emitting output line EMOUTL(j).

In an exemplary embodiment, as shown in FIG. 7, an orthographic projection of the (2j−1)-th reference output line REFOUTL(2j−1) on the substrate at least partially overlaps an orthographic projection of the (2j−1)-th reference signal line REF(2j−1) on the substrate, and the (2j−1)-th reference output line REFOUTL(2j−1) is electrically connected with the (2j−1)-th reference signal line REF(2j−1).

In an exemplary embodiment, as shown in FIG. 7, an orthographic projection of the 2j-th reference output line REFOUTL(2j) on the substrate at least partially overlaps an orthographic projection of the 2j-th reference signal line REF(2j) on the substrate, and the 2j-th reference output line REFOUTL(2j) is electrically connected with the 2j-th reference signal line REF(2j) In an exemplary embodiment, as shown in FIG. 7, the distance between the boundary of the reference power supply line REFL away from the display region and the boundary of the (2j−1)-th first scan output line GOUTL1(2j−1) close to the display region may be substantially equal to the distance between the boundary of the reference power supply line REFL away from the display region and the boundary of the second signal connection line close to the display region, and the distance is a.

In an exemplary embodiment, as shown in FIG. 7, the length of the (2j−1)-th first scan output line GOUTL1(2j−1) in the second direction is substantially equal to the length of the second signal connection line 32 in the second direction, and the length is b.

In an exemplary embodiment, as shown in FIG. 7, when the length in the first direction of the overlapping region of the first signal connection line 31 and the (2j−1)-th first scan output line GOUTL1(2j−1) is c, and the length in the first direction of the overlapping region of the second scan connection part and the (2j−1)-th first scan output line GOUTL1(2j−1) is also c, the length d of the second light emitting output part EOLB in the first direction may be 2c microns in order to ensure that the RC of the first signal lines electrically connected with adjacent first scan signal lines is the same. For example, when c=6, d=12.

In an exemplary embodiment, as shown in FIG. 7, there may be an error between the actual value of the first scan output line and the theoretical value, and exemplarily, the actual value of the first scan output line may be 2 microns smaller than the theoretical value.

In an exemplary embodiment, when a=475 microns, b=10 microns, c=6 microns, and d=12 microns, the resistance R of the (2j−1)-th first scan output line GOUTL1(2j−1) located between the boundary of the reference power supply line REFL away from the display region and the boundary of the (2j−1)-th first scan output line GOUTL1(2j−1) close to the display region satisfies R=Rs*a/b=0.03*475/10=1.425Ω, where Rs is the square resistance of the first conductive layer. Herein, a and b are actual values, the capacitance value C₁ located in the region R1 satisfies C₁=K*S/D, where K is the dielectric constant, S is the area of the overlapping region, D is the thickness of the second conductive layer, and S=2*10 microns*6 microns=120 square microns. The resistance R₂ of the (2j−1)-th first scan output line GOUTL1(2j−1) and the first signal connection line located between the boundary of the reference power supply line REFL away from the display region and the boundary of the second signal connection line close to the display region satisfies R₂=Rs*a/b=0.03*475/10=1.425Ω, is the same as the resistance R₁ of the (2j−1)-th first scan output line GOUTL1(2j−1) located between the boundary of the reference power supply line REFL away from the display region and the boundary of the (2j−1)-th first scan output line GOUTL1(2j−1) close to the display region. In addition, the capacitance value C₂ located in the region R2 satisfies C₂=10 microns*12 microns=120 square microns, which is equal to the capacitance value C₁ located in the region R1, that is, the first signal line electrically connected with the (2j−1)-th first scan signal line and the first signal line electrically connected with the 2j-th first scan signal line have equal resistance in a same region; and overlapping regions between the first signal line electrically connected with the (2j−1)-th first scan signal line and the corresponding second signal line and between the first signal line electrically connected with the 2j-th first scan signal line and the corresponding second signal line have equal capacitance values in the present disclosure.

In an exemplary embodiment, when the difference between the square resistances of the first signal line electrically connected with the (2j−1)-th first scan signal line and the first signal line electrically connected with the 2j-th first scan signal line is large, different manufacturing materials can be used or the direction of the signal lines can be changed so that the first signal line electrically connected with the (2j−1)-th first scan signal line and the first signal line electrically connected with the 2j-th first scan signal line have equal resistance in a same region and have equal capacitance values with respect to overlapping regions between them and the corresponding second signal lines.

In an exemplary embodiment, the drive circuit layer may further include a shielding layer located on a side of the first conductive layer close to the substrate. The shielding layer at least includes a reference signal line and an initial signal line.

In an exemplary embodiment, the drive circuit layer may further include a semiconductor layer located between the shielding layer and the first conductive layer, and the semiconductor layer may at least include an active layer of a plurality of transistors.

In an exemplary embodiment, a storage capacitor in the pixel drive circuit may include a first electrode plate, a second electrode plate, and a third electrode plate, wherein the first electrode plate and the third electrode plate are electrically connected. Exemplarily, the first electrode plate may be located in the shielding layer, the second electrode plate may be located in the semiconductor layer, and the third electrode plate may be located in the second conductive layer. In an exemplary embodiment, the storage capacitor includes three electrode plates, which can enhance the storage capacity of the storage capacitor, ensure the stability of the signal of the first node in the pixel drive circuit, and improve the reliability of the display panel.

In an exemplary embodiment, the display panel may further include a first insulating layer located between the shielding layer and the semiconductor layer, a second insulating layer located between the semiconductor layer and the first conductive layer, a third insulating layer located between the first conductive layer and the second conductive layer, and a fourth insulating layer and a planarization layer located on a side of the second conductive layer away from the substrate.

A preparation process of the display panel will be exemplarily described below. “Patterning processes” mentioned in the present disclosure include photoresist coating, mask exposure, development, etching, photoresist stripping, etc., for metal materials, inorganic materials or transparent conductive materials, and include organic material coating, mask exposure, development, etc., for organic materials. Deposition may be any one or more of sputtering, evaporation, and chemical vapor deposition. Coating may be any one or more of spray coating, spin coating, and inkjet printing. Etching may be any one or more of dry etching and wet etching, which is not limited in the present disclosure. “Film” refers to a layer of film formed from a certain material on a substrate using deposition, coating or other processes. If the “film” does not need to be processed through a patterning process in the entire manufacturing process, the “film” may also be called a “layer”. If the “film” needs to be processed through the patterning process in the entire manufacturing process, the “film” is called a “film” before the patterning process is performed and is called a “layer” after the patterning process is performed. At least one “pattern” is contained in the “layer” which has been processed through the patterning process. “A and B are provided on a same layer” described in the present disclosure means that A and B are formed at the same time through a same patterning process, and a “thickness” of a film layer is a dimension of the film layer in a direction perpendicular to a display panel. In an exemplary implementation of the present disclosure, “an orthographic projection of B is within a range of an orthographic projection of A” or “an orthographic projection of A includes an orthographic projection of B” refers to that a boundary of an orthographic projection of B falls within a range of a boundary of an orthographic projection of A, or the boundary of an orthographic projection of A is overlapped with the boundary of an orthographic projection of B.

In an exemplary embodiment, a manufacturing process of a display panel may include following operations.

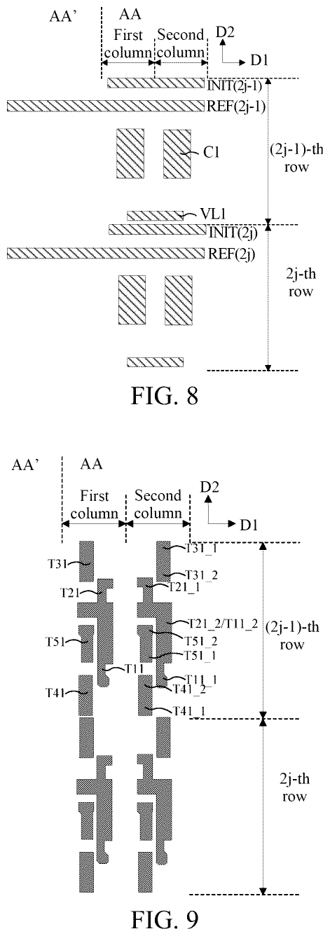

(1) A pattern of a shielding layer is formed. In an exemplary embodiment, forming the pattern of the shielding layer may include sequentially depositing a shielding film on a substrate, patterning the shielding film through a patterning process, and forming the pattern of the shielding layer covering the substrate. FIG. 8 is a schematic view of the display panel provided in FIGS. 5 to 7 after a pattern of a shielding layer is formed. FIG. 8 is illustrated by taking the pixel circuits in the (2j−1)-th row and the first column, the (2j−1)-th row and the second column, the 2j-th row and the first column, and the 2j-th row and the second column in the display region AA as an example.

In an exemplary embodiment, as shown in FIG. 8, the pattern of the shielding layer may include at least a first electrode plate C1 and a first connection line VL1 of a storage capacitor of a sub-pixel located in the display region, and an initial signal line and a reference signal line at least partially located in the display region. FIG. 8 is illustrated by taking a case in which the initial signal line is located in the display region, the reference signal line is located in the display region AA and the non-display region AA′ as an example, and only the (2j−1)-th initial signal line INIT(2j−1), the 2j-th initial signal line INIT(2j), the reference signal line REF(2j−1) and the 2j-th reference signal line REF(2j) are shown in FIG. 8.

In an exemplary embodiment, as shown in FIG. 8, the initial signal line, the reference signal line, and the first connection line VL1 extend in the first direction D1, and the initial signal line electrically connected with the same pixel drive circuit is located on a side of the electrically connected reference signal line away from the first electrode plate of the storage capacitor of the pixel drive circuit. Exemplarily, the (2j−1)-th initial signal line INIT(2j−1) electrically connected with the (2j−1)-th row of pixel drive circuits is located on a side of the (2j−1)-th reference signal line REF(2j−1) electrically connected with the (2j−1)-th row of pixel drive circuits away from the first electrode plate C1 of the storage capacitor of the (2j−1)-th row of pixel drive circuits, and the 2j-th initial signal line INIT(2j) electrically connected with the 2j-th row of pixel drive circuits is located on a side of the 2j-th reference signal line REF(2j) electrically connected with the 2j-th row of pixel drive circuits away from the first electrode plate C1 of the storage capacitor of the 2j-th row of pixel drive circuits.

In an exemplary embodiment, as shown in FIG. 8, the first electrode plate C1 of the storage capacitor is of a strip structure and is located between the reference signal line electrically connected with the pixel drive circuit where the storage capacitor is located and the first connection line of the pixel drive circuit where the storage capacitor is located, and, exemplarily, the first electrode plate C1 of the storage capacitor of the (2j−1)-th row of the pixel drive circuits is located between the (2j−1)-th reference signal line REF(2j−1) electrically connected with the (2j−1)-th row of the pixel drive circuits and the first connection line VL1 of the (2j−1)-th row of the pixel drive circuits. The first electrode C1 of the storage capacitor of the 2j-th row of pixel drive circuits is located between the 2j-th reference signal line REF(2j) electrically connected with the 2j-th row of pixel drive circuits and the first connection line VL1 of the 2j-th row of pixel drive circuits.

In an exemplary embodiment, the initial signal line and the scan signal line may be in an equal width design, or may be in a non-equal width design, may be straight lines, or may be bend lines, which may not only facilitate the layout of the pixel structure, but also reduce the parasitic capacitance between the signal lines, and this is not limited in the present disclosure.

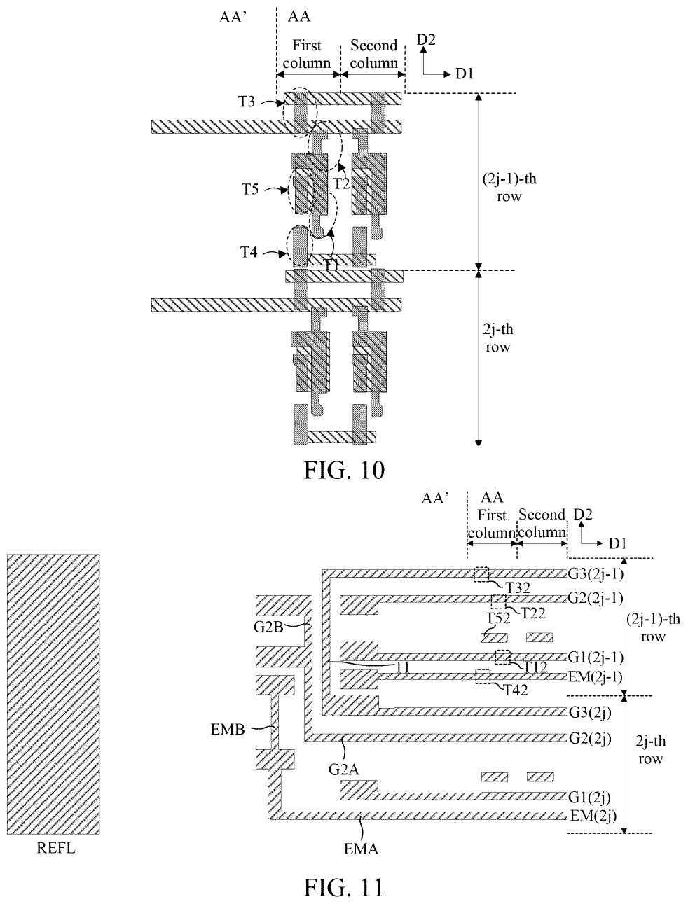

(2) A pattern of a semiconductor layer is formed. In an exemplary embodiment, forming a pattern of a semiconductor layer may include sequentially depositing a first insulating film and a semiconductor film on a substrate, patterning the semiconductor film through a patterning process to form a first insulating layer covering the substrate, and a pattern of a semiconductor layer disposed on the first insulating layer, as shown in FIGS. 9 and 10, FIG. 9 is a schematic diagram of a pattern of a semiconductor layer of the display panel provided in FIGS. 5 to 7, and FIG. 10 is a schematic diagram of the display panel provided in FIGS. 5 to 7 after a pattern of a semiconductor layer is formed.

In an exemplary embodiment, as shown in FIGS. 9 and 10, the pattern of the semiconductor layer may include at least an active layer T11 of the first transistor T1 to an active layer T51 of the fifth transistor T5 of each sub-pixel located in the display region.

In an exemplary embodiment, the active layer T11 of the first transistor and the active layer T21 of the second transistor are interconnected to be of an integral structure. The active layer T31 of the third transistor, the active layer T41 of the fourth transistor, and the active layer T51 of the fifth transistor are provided separately.

In an exemplary embodiment, in the first direction D1, the active layer T31 of the third transistor, the active layer T41 of the fourth transistor, and the active layer T51 of the fifth transistor may be located on a same side of the integral structure of the active layer T11 of the first transistor and the active layer T21 of the second transistor in the present sub-pixel. In the second direction D2, the active layer T31 of the third transistor in the present row of sub-pixels may be located on a side of the integral structure of the active layer T11 of the first transistor and the active layer T21 of the second transistor close to the previous row of sub-pixels, the active layer T41 of the fourth transistor in the present row of sub-pixels may be located on a side of the integral structure of the active layer T11 of the first transistor and the active layer T21 of the second transistor close to the next row of sub-pixels, and the active layer T51 of the fifth transistor in the present column of sub-pixels may be located on a side of the integral structure of the active layer T11 of the first transistor and the active layer T21 of the second transistor close to the previous column of sub-pixels.

In an exemplary embodiment, the active layer T31 of the third transistor, the active layer T41 of the fourth transistor, and the active layer T51 of the fifth transistor may be in the shape of a strip structure, the active layer T11 of the first transistor may have a shape of a “7”, and the active layer T21 of the second transistor may have a shape of a horizontally reversed “7”.

In an exemplary implementation, an active layer of each transistor may include a first area, a second area, and a channel area located between the first area and the second area. In an exemplary embodiment, the second area T11_2 of the active layer T11 of the first transistor may be used as the second area T21_2 of the active layer T21 of the second transistor, and the first and second areas of the active layer of the remaining transistors except the second area T11_2 of the active layer T11 of the first transistor and the second area of the active layer T21 of the second transistor may be provided separately.

In an exemplary embodiment, an orthographic projection of the first electrode plate of the storage capacitor on the substrate at least partially overlaps an orthographic projection of the integral structure of the active layer T51 of the fifth transistor, the active layer T11 of the first transistor and the active layer T21 of the second transistor on the substrate. The first electrode plate of the storage capacitor can shield the active layer T51 of the fifth transistor, thereby avoiding the influence of light on the active layer of the drive transistor and improving the reliability of the pixel drive circuit.

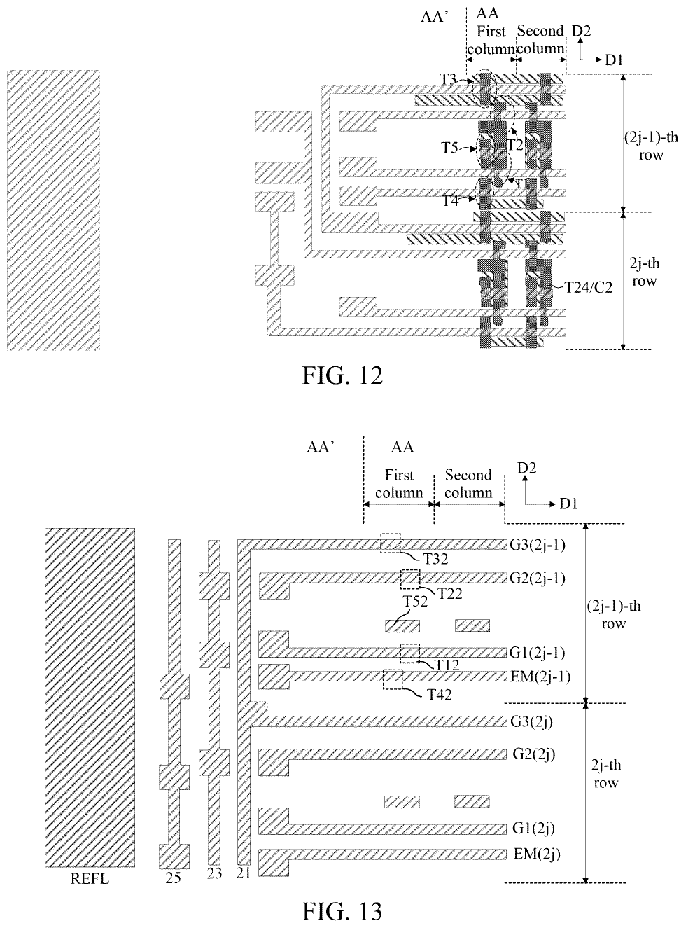

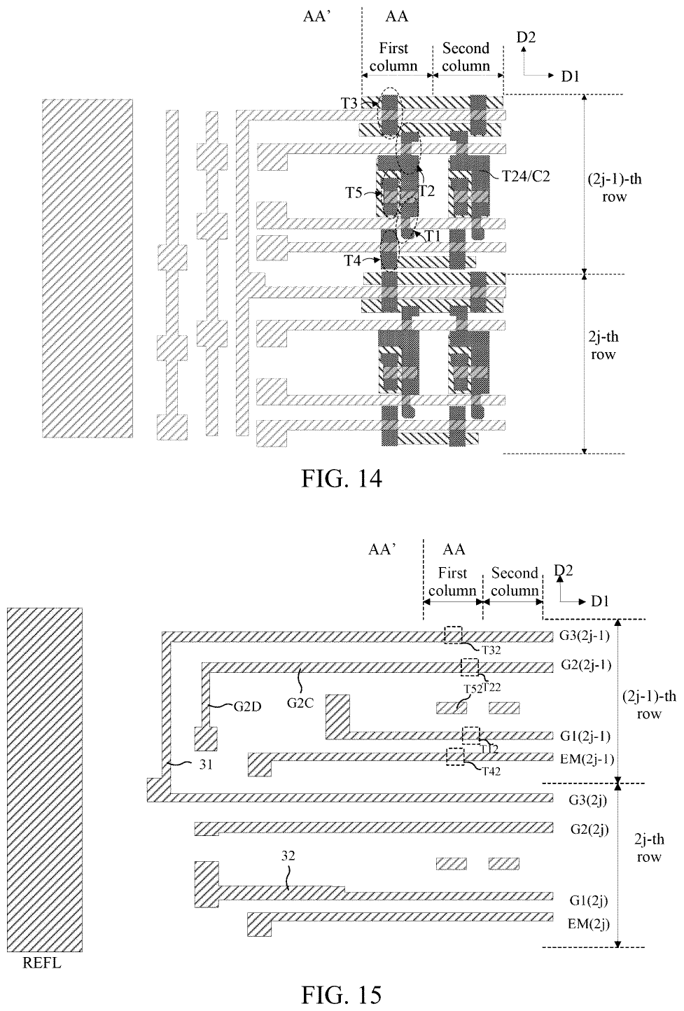

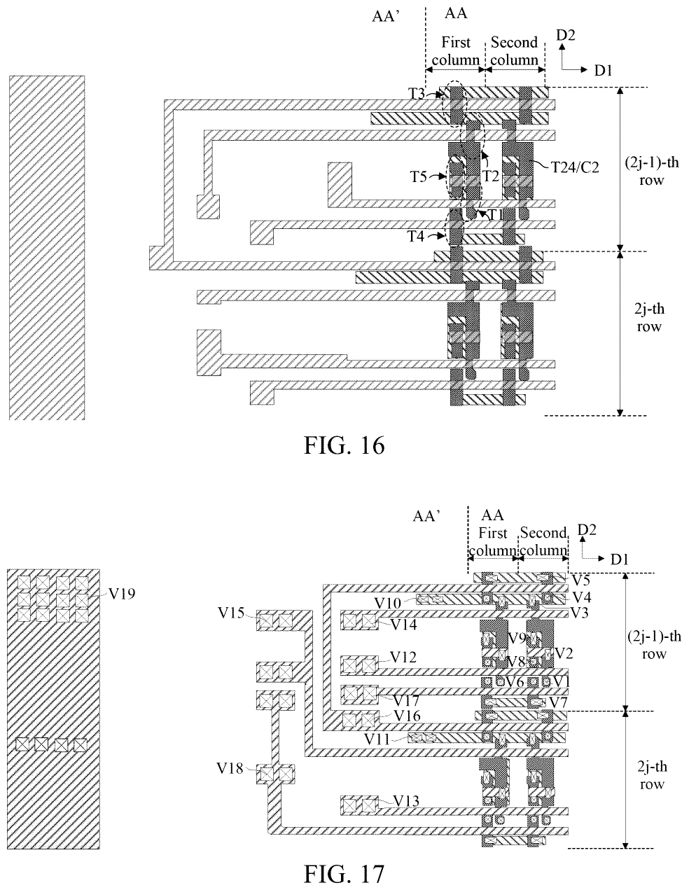

(3) A pattern of a first conductive layer is formed. In an exemplary embodiment, forming a pattern of a first conductive layer may include sequentially depositing a second insulating film and a first conductive film on the substrate on which the above-mentioned patterns are formed, patterning the first conductive film through a patterning process to form a second insulating layer covering the pattern of the semiconductor layer and a pattern of a first conductive layer disposed on the second insulating layer, as shown in FIGS. 11 to 16, wherein FIG. 11 is a schematic diagram of a pattern of a first conductive layer of the display panel provided in FIG. 5, FIG. 12 is a schematic diagram of the display panel provided in FIG. 5 after a pattern of a first conductive layer is formed, FIG. 13 is a schematic diagram of a pattern of a first conductive layer of the display panel provided in FIG. 6, FIG. 14 is a schematic diagram of the display panel provided in FIG. 6 after a pattern of a first conductive layer is formed, FIG. 15 is a schematic diagram of a pattern of a first conductive layer of the display panel provided in FIG. 7, and FIG. 16 is a schematic diagram of the display panel provided in FIG. 7 after a pattern of a first conductive layer is formed. In an exemplary embodiment, the first conductive layer may be referred to as a gate metal (GATE) layer. Only the (2j−1)-th first scan signal line G1(2j−1), the 2j-th first scan signal line G1(2j), the (2j−1)-th second scan signal line G2(2j−1), the 2j-th second scan signal line G2(2j), the (2j−1)-th third scan signal line G3(2j−1), the 2j-th second scan signal line G3(2j), the (2j−1)-th light emitting signal line EM(2j−1) and the 2j-th light emitting signal line EM(2j) are shown in FIGS. 11 to 16.

In an exemplary embodiment, as shown in FIGS. 11 to 16, the pattern of the first conductive layer may include at least a control electrode T12 of a first transistor to a control electrode T52 of a fifth transistor of a sub-pixel located in the display region, a first scan signal line, a second scan signal line, a third scan signal line and a light emitting signal line located at least partially in the display region, and a reference power supply line REFL located in the non-display region.

In an exemplary embodiment, as shown in FIGS. 11 to 16, at least portions of the first scan signal line, the second scan signal line, the third scan signal line and the light emitting signal line extend in the first direction D1, and the reference power supply line REFL extends in the second direction D2.

In an exemplary implementation, the first scan signal line, the second scan signal line, the third scan signal line, and the light emitting signal line may be in an equal width design, or may be in a non-equal width design, may be straight lines, or may be bend lines, which may not only facilitate the layout of the pixel structure, but also reduce the parasitic capacitance between the signal lines, and this is not limited in the present disclosure.

In an exemplary embodiment, as shown in FIGS. 11 to 16, for each sub-pixel, an overlapping region of the third scan signal line electrically connected with the sub-pixel and the active layer of the third transistor serves as a control electrode T32 of the third transistor of the present sub-pixel, an overlapping region of the second scan signal line electrically connected with the sub-pixel and the active layer of the second transistor serves as a control electrode T22 of the second transistor of the present sub-pixel, an overlapping region of the first scan signal line electrically connected with the sub-pixel and the active layer of the first transistor serves as a control electrode T12 of the first transistor of the present sub-pixel, an overlapping region of the light emitting signal line electrically connected with the sub-pixel and the active layer of the fourth transistor serves as a control electrode T42 of the fourth transistor of the present sub-pixel, a control electrode T52 of the fifth transistor of each sub-pixel is located between the second scan signal line and the first scan signal line electrically connected with the present sub-pixel.

In an exemplary embodiment, the control electrode T52 of the fifth transistor extends in the first direction D1.

In an exemplary embodiment, as shown in FIGS. 11 to 16, the i-th third scan signal line, the i-th reference signal line, the i-th second scan signal line, the i-th first scan signal line, and the i-th light emitting signal line are arranged sequentially along the second direction D2, the i-th third scan signal line is located on a side of the i-th reference signal line close to the (i−1)-th light emitting signal line, and the i-th light emitting signal line is located on a side of the i-th first scan signal line close to the (i+1)-th third scan signal line. Exemplarily, the (2j−1)-th third scan signal line G3(2j−1), the (2j−1)-th reference signal line REF(2j−1), the (2j−1)-th second scan signal line G2(2j−1), the (2j−1)-th first scan signal line G1(2j−1) and the (2j−1)-th light emitting signal line EM(2j−1) are arranged along the second direction D2, the (2j−1)-th third scan signal line G3(2j−1) is located on a side of the (2j−1)-th reference signal line REF(2j−1) close to the (2j−2)-th light emitting signal line EM(2j−2), and the (2j−1)-th light emitting signal line EM(2j−1) is located on a side of the (2j−1)-th first scan signal line G1(2j−1) close to the 2j-th third scan signal G3(2j).

In an exemplary embodiment, an orthographic projection of the i-th third scan signal line on the substrate is located between an orthographic projection of the i-th initial signal line on the substrate and an orthographic projection of the i-th reference signal line on the substrate. Exemplarily, an orthographic projection of the 2j-th third scan signal line G3(2j) on the substrate is located between an orthographic projection of the 2j-th initial signal line INIT(2j) on the substrate and an orthographic projection of the 2j-th reference signal line REF(2j) on the substrate.

In an exemplary embodiment, as shown in FIGS. 11 and 12, the pattern of the first conductive layer of the display panel provided in FIG. 5 may further include a first signal connection line 11 electrically connected with the (2j−1)-th third scan signal line G3(2j−1) and the 2j-th second scan signal line G3(2j).

In an exemplary embodiment, as shown in FIGS. 11 and 12, the first signal connection line 11 may extend in the second direction D2, and the first signal connection line 11 may be located on a side of the reference power supply line REFL close to the display region.

In an exemplary embodiment, as shown in FIGS. 11 and 12, the first signal connection line 11 is integrally structured with the (2j−1)-th third scan signal line G3(2j−1) and the 2j-th second scan signal line G3(2j).

In an exemplary embodiment, as shown in FIGS. 11 and 12, the (2j−1)-th first scan signal line G1(2j−1), the 2j-th first scan signal line G1(2j), the (2j−1)-th second scan signal line G2(2j−1), the (2j−1)-th third scan signal line G3(2j−1), the 2j-th third scan signal line G3(2j), and the (2j−1)-th light emitting signal line EM(2j−1) extend in the first direction D1.

In an exemplary embodiment, as shown in FIGS. 11 and 12, the 2j-th second scan signal line G2(2j) includes a first scan connection part G2A and a second scan connection part G2B connected with each other. The first scan connection part G2A extends in the first direction D1, the second scan connection part G2B extends in the second direction D2, and the first signal connection line 11 is located on a side of the second scan connection part G2B close to the display region AA.

In an exemplary embodiment, as shown in FIGS. 11 and 12, the 2j-th light emitting signal line EM(2j) may include a first light emitting connection part EMA extending in the first direction D1 and a second light emitting connection part EMB extending in the second direction D2, which are connected with each other, and the second light emitting connection part EMB is located between the reference power supply line REFL and the second scan connection part G2B.

In an exemplary embodiment, as shown in FIGS. 13 and 14, the pattern of the first conductive layer of the display panel provided in FIG. 6 further includes a first signal connection line 21, a second signal connection line 22 and a fifth signal connection line 25.

In an exemplary embodiment, as shown in FIGS. 13 and 14, the first signal connection line 21 is electrically connected with the (2j−1)-th third scan signal line G3(2j−1) and the 2j-th second scan signal line G3(2j), and is integrally constructed with the (2j−1)-th third scan signal line G3(2j−1) and the 2j-th second scan signal line G3(2j).

In an exemplary embodiment, as shown in FIGS. 13 and 14, the first signal connection line 21, the second signal connection line 22 and the fifth signal connection line 25 may extend in the second direction D2. The first signal connection line 21, the second signal connection line 22, and the fifth signal connection line 25 may be located on a side of the reference power supply line REF close to the display region, the first signal connection line 21 and the second signal connection line 22 may be located on a side of the fifth signal connection line 25 close to the display region, and the first signal connection line 21 may be located on a side of the second signal connection line 22 close to the display region.

In an exemplary embodiment, the first signal connection line, the second signal connection line, and the fifth signal connection line may be in an equal width design, or may be in a non-equal width design, may be straight lines, or may be bend lines, which may not only facilitate the layout of the pixel structure, but also reduce the parasitic capacitance between the signal lines, and this is not limited in the present disclosure.

In an exemplary embodiment, as shown in FIGS. 13 and 14, the (2j−1)-th first scan signal line G1(2j−1), the 2j-th first scan signal line G1(2j), the (2j−1)-th second scan signal line G2(2j−1), the 2j-th second scan signal line G2(2j), the (2j−1)-th third scan signal line G3(2j−1), the 2j-th third scan signal line G3(2j), the (2j−1)-th light emitting signal line EM(2j−1) and the 2j-th light emitting signal line EM(2j) all extend in the first direction D1.

In an exemplary embodiment, as shown in FIGS. 15 and 16, the pattern of the first conductive layer of the display panel provided in FIG. 7 further includes a first signal connection line 31 electrically connected with the (2j−1)-th third scan signal line G3(2j−1) and the 2j-th second scan signal line G3(2j) and a second signal connection line 32 electrically connected with the 2j-th first scan signal line G1(2j).

In an exemplary embodiment, as shown in FIGS. 15 and 16, the first signal connection line 31 may extend in the second direction D2 and may be located on a side of the reference power supply line REF close to the display region.

In an exemplary embodiment, as shown in FIGS. 15 and 16, the second signal connection line 32 may extend in the first direction D1, and the length of the second signal connection line 32 in the second direction is greater than the width of the 2j-th first scan signal line G1(2j) in the second direction D2.

In an exemplary embodiment, as shown in FIGS. 15 and 16, the (2j−1)-th first scan signal line G1(2j−1), the 2j-th first scan signal line G1(2j), the 2j-th second scan signal line G2(2j), the (2j−1)-th third scan signal line G3(2j−1), the 2j-th third scan signal line G3(2j), the (2j−1)-th light emitting signal line EM(2j−1) and the 2j-th light emitting signal line EM(2j) all extend in the first direction D1.

In an exemplary embodiment, as shown in FIGS. 15 and 16, the (2j−1)-th second scan signal line G2(2j−1) includes a first scan connection part G2C extending in the first direction D1 and a second scan connection part G2D extending in the second direction D2, which are connected with each other.

In an exemplary implementation, after the pattern of the first conductive layer is formed, the semiconductor layer may be subjected to a conductive treatment by using the first conductive layer as a shield. An area of the semiconductor layer, which is shielded by the first conductive layer, forms channel areas of the first transistor T1 to the fifth transistor T5, and an area of the semiconductor layer, which is not shielded by the first conductive layer, is made to be conductive, that is, the first area and the second area of the active layer of the first transistor to the fifth transistor are all made to be conductive. As shown in FIGS. 12, 14, and 16, the second area of the active layer of the second transistor (also the second area of the active layer of the first transistor) is multiplexed into a second electrode plate C2 of the storage capacitor and a second electrode T24 of the second transistor.

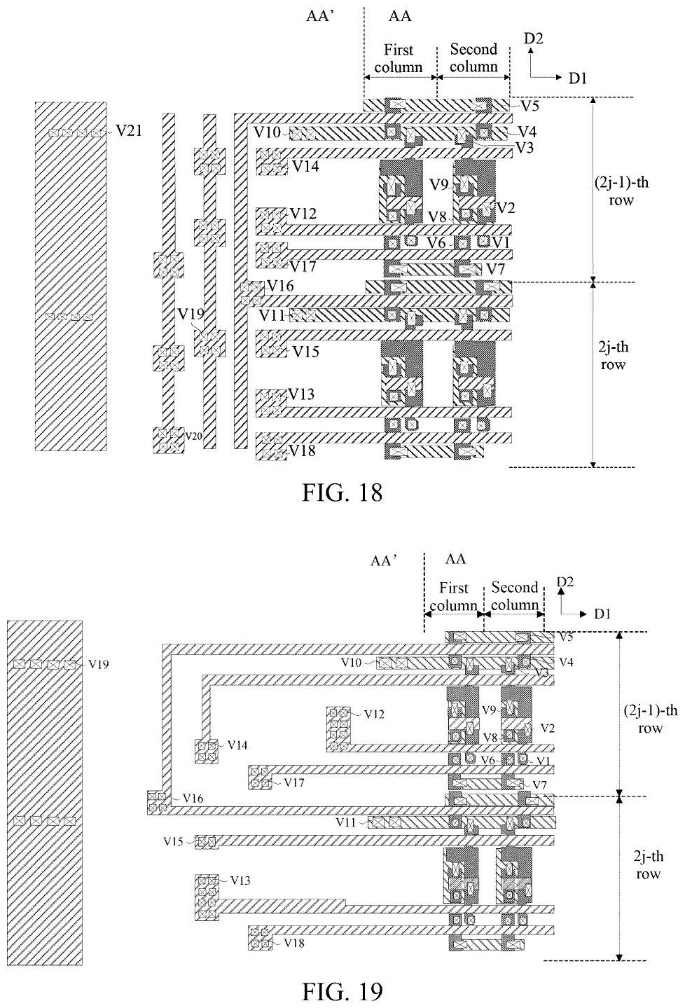

(4) A pattern of a third insulation layer is formed. In an exemplary embodiment, forming a pattern of a third insulating layer may include depositing a third insulating film on the substrate on which the above-mentioned patterns are formed, patterning the third insulating film using a patterning process to form a third insulating layer covering the first conductive layer, the third insulating layer is provided with a plurality of vias, as shown in FIGS. 17 to 19, wherein FIG. 17 is a schematic diagram of the display panel provided in FIG. 5 after a pattern of a third insulating layer is formed, FIG. 18 is a schematic diagram of the display panel provided in FIG. 6 after a pattern of a third insulating layer is formed and FIG. 19 is a schematic diagram of the display panel provided in FIG. 7 after a pattern of a third insulating layer is formed.

In an exemplary embodiment, as shown in FIG. 17, the plurality of vias in the display panel provided in FIG. 5 may include at least a first via V1 to a ninth via V9 located in each sub-pixel of the display region AA and a tenth via V10 to a nineteenth via V19 located in the non-display region AA′.

In an exemplary manner, the quantity of any one of the tenth via V10 to the twenty-first via V21 may be multiple, and any one of the tenth via V10 to the twenty-first via V21 may be arranged in an array, which is not limited in the present disclosure.

In an exemplary embodiment, as shown in FIG. 17, an orthographic projection of the first via V1 on the substrate is within the range of an orthographic projection of the first area of the active layer of the first transistor on the substrate, the third insulating layer and the second insulating layer within the first via V1 are removed to expose the surface of the first area of the active layer of the first transistor, and the first via V1 is configured to connect the first electrode of the subsequently formed first transistor to the first area of the active layer of the first transistor through the via V1.

In an exemplary embodiment, as shown in FIG. 17, an orthographic projection of the second via V2 on the substrate is within the range of an orthographic projection of the control electrode of the fifth transistor and the second area of the active layer of the first transistor (also the second area and the second electrode plate of the active layer of the second transistor) on the substrate, the third insulating layer and the second insulating layer within the second via V2 are removed to expose the surface of the second area of the active layer of the first transistor, the third insulating layer within the second via V2 is removed to expose the control electrode of the fifth transistor, and the second via V2 is configured to connect the second electrode of the subsequently formed first transistor to the control electrode of the fifth transistor and the second area of the active layer of the first transistor (also the second area and the second electrode plate of the active layer of the second transistor) through the via V2.

In an exemplary embodiment, as shown in FIG. 17, an orthographic projection of the third via V3 on the substrate is within the range of an orthographic projection of the first area of the active layer of the second transistor and the reference signal line electrically connected with the sub-pixel on the substrate, the third insulating layer and the second insulating layer within the third via V3 are removed to expose the surface of the first area of the active layer of the second transistor, the first to third insulating layers in the third via V3 are removed to expose the surface of the reference signal line electrically connected with the sub-pixel, and the third via V3 is configured to connect a first electrode of the subsequently formed second transistor to the first area of the active layer of the second transistor and the reference signal line electrically connected with the sub-pixel through the via V3.

In an exemplary embodiment, as shown in FIG. 17, an orthographic projection of the fourth via V4 on the substrate is within the range of an orthographic projection of the second area of the active layer of the third transistor on the substrate, the third insulating layer and the second insulating layer within the fourth via V4 are removed to expose the surface of the second area of the active layer of the third transistor, and the fourth via V4 is configured to connect a second electrode of the subsequently formed third transistor to the second area of the active layer of the third transistor through the via V4.

In an exemplary embodiment, as shown in FIG. 17, an orthographic projection of the fifth via V5 on the substrate is within the orthographic projection of the first area of the active layer of the third transistor and the initial signal line electrically connected with the sub-pixel on the substrate, the third insulating layer and the second insulating layer within the fifth via V5 are removed to expose the surface of the first area of the active layer of the third transistor, the first to third insulating layers in the fifth via V5 are removed to expose the surface of the initial signal line electrically connected with the sub-pixel, and the fifth via V5 is configured to connect a first electrode of the subsequently formed third transistor with the first area of the active layer of the third transistor and the initial signal line electrically connected with the sub-pixel through the via V5.

In an exemplary embodiment, as shown in FIG. 17, an orthographic projection of the sixth via V6 on the substrate is within the range of an orthographic projection of the second area of the active layer of the fourth transistor on the substrate, the third insulating layer and the second insulating layer within the sixth via V6 are removed to expose the surface of the second area of the active layer of the fourth transistor, and the sixth via V6 is configured to connect a second electrode of the subsequently formed fourth transistor to the second area of the active layer of the fourth transistor through the via V6.

In an exemplary embodiment, as shown in FIG. 17, an orthographic projection of the seventh via V7 on the substrate is within the range of an orthographic projection of the first area of the active layer of the fourth transistor and the first connection line on the substrate, the third insulating layer and the second insulating layer within the seventh via V7 are removed to expose the surface of the first area of the active layer of the fourth transistor, the first to third insulating layers in the seventh via V7 are removed to expose the surface of the first connection line, and the seventh via V7 is configured to connect the first electrode of the subsequently formed fourth transistor to the first area of the active layer of the fourth transistor and the first connection line through the via V7.

In an exemplary embodiment, as shown in FIG. 17, an orthographic projection of the eighth via V8 on the substrate is within the range of an orthographic projection of the first area of the active layer of the fifth transistor on the substrate, the third insulating layer and the second insulating layer within the eighth via V8 are removed to expose the surface of the first area of the active layer of the fifth transistor, and the eighth via V8 is configured to connect a first electrode of the subsequently formed fifth transistor to the first area of the active layer of the fifth transistor through the via V8.

In an exemplary embodiment, as shown in FIG. 17, an orthographic projection of the ninth via V9 on the substrate is within the range of an orthographic projection of the second area of the active layer of the fifth transistor and the first electrode plate on the substrate, the third and second insulating layers in the ninth via V9 are removed to expose the surface of the second area of the active layer of the fifth transistor, the first to third insulating layers in the ninth via V9 are removed to expose the surface of the first electrode plate, and the ninth via V9 is configured to connect a second electrode of the subsequently formed fifth transistor to the second area of the active layer of the fifth transistor and the first electrode plate through the via.

In an exemplary embodiment, as shown in FIG. 17, an orthographic projection of the tenth via V10 on the substrate is within the range of an orthographic projection of the (2j−1)-th reference signal line REF(2j−1) on the substrate, the first to third insulating layers in the tenth via V10 are removed to expose the surface of the (2j−1)-th reference signal line REF(2j−1), and the tenth via V10 is configured to connect the subsequently formed (2j−1)-th reference output line REFOUTL(2j−1) to the (2j−1)-th reference signal line REF(2j−1) through the via V10.

In an exemplary embodiment, as shown in FIG. 17, an orthographic projection of the eleventh via V11 on the substrate is within the range of an orthographic projection of the 2j-th reference signal line REF(2j) on the substrate, the first to third insulating layers in the tenth via V10 are removed to expose the surface of the 2j-th reference signal line REF(2j), and the eleventh via V11 is configured to connect the subsequently formed 2j-th reference output line REFOUTL(2j) to the (2j−1)-th reference signal line REF(2j) through the via V11.

In an exemplary embodiment, as shown in FIG. 17, an orthographic projection of the twelfth via V12 on the substrate is within the range of an orthographic projection of the (2j−1)-th first scan signal line G1(2j−1) on the substrate, the third insulating layer within the twelfth via V12 is removed to expose the surface of the (2j−1)-th first scan signal line G1(2j−1), and the twelfth via V12 is configured to connect the subsequently formed (2j−1)-th first scan output line GOUTL1(2j−1) to the (2j−1)-th first scan signal line G1(2j−1) through the via V12.

In an exemplary embodiment, as shown in FIG. 17, an orthographic projection of the thirteenth via V13 on the substrate is within the range of an orthographic projection of the 2j-th first scan signal line G1(2j) on the substrate, the third insulating layer within the thirteenth via V13 is removed to expose the surface of the 2j-th first scan signal line G1(2j), and the thirteenth via V13 is configured to connect the subsequently formed 2j-th first scan output line GOUTL1(2j) to the 2j-th first scan signal line G1(2j) through the via V13.

In an exemplary embodiment, as shown in FIG. 17, an orthographic projection of the fourteenth via V14 on the substrate is within the range of an orthographic projection of the (2j−1)-th second scan signal line G2(2j−1) on the substrate, the third insulating layer within the fourteenth via V14 is removed to expose the surface of the (2j−1)-th second scan signal line G2(2j−1), and the fourteenth via V14 is configured to connect the subsequently formed second signal connection line to the (2j−1)-th second scan signal line G2(2j−1) through the via V14.

In an exemplary embodiment, as shown in FIG. 17, an orthographic projection of the fifteenth via V15 on the substrate is within the range of an orthographic projection of the second scan connection part of the 2j-th second scan signal line G2(2j) on the substrate, the third insulating layer within the fifteenth via V15 is removed to expose the surface of the second scan connection part of the 2j-th second scan signal line G2(2j), and the fifteenth via V15 is configured to connect the subsequently formed j-th second scan output line GOUTL2(j) and the second signal connection line to the 2j-th second scan signal line G2(2j) through the via V15.

In an exemplary embodiment, as shown in FIG. 17, an orthographic projection of the sixteenth via V16 on the substrate is within the range of an orthographic projection of the 2j-th third scan signal line G3(2j) on the substrate, the third insulating layer within the sixteenth via V16 is removed to expose the surface of the 2j-th third scan signal line G3(2j), and the sixteenth via V16 is configured to connect the subsequently formed j-th third scan output line GOUTL3(j) to the 2j-th third scan signal line G3(2j) through the via V16.

In an exemplary embodiment, as shown in FIG. 17, an orthographic projection of the seventeenth via V17 on the substrate is within the range of an orthographic projection of the (2j−1)-th light emitting signal line EM(2j−1) on the substrate, the third insulating layer within the seventeenth via V17 is removed to expose the surface of the (2j−1)-th light emitting signal line EM(2j−1), and the seventeenth via V17 is configured to connect a subsequently formed third signal connection line to the (2j−1)-th light emitting signal line EM(2j−1) through the via V17.

In an exemplary embodiment, as shown in FIG. 17, an orthographic projection of the eighteenth via V18 on the substrate is within the range of an orthographic projection of the second light emitting connection part of the 2j-th light emitting signal line EM(2j) on the substrate, the third insulating layer within the eighteenth via V18 is removed to expose the surface of the second light emitting connection part of the 2j-th light emitting signal line EM(2j), and the eighteenth via V18 is configured to connect the subsequently formed j-th light emitting output line and the third signal connection line to the 2j-th light emitting signal line EM(2j) through the via V18.

In an exemplary embodiment, as shown in FIG. 17, an orthographic projection of the nineteenth via V19 on the substrate is within the range of an orthographic projection of the reference power supply line on the substrate, the third insulating layer within the nineteenth via V19 is removed to expose the surface of the reference power supply line, and the nineteenth via V19 is configured to connect the subsequently formed reference output line to the reference power supply line through the via V19.

In an exemplary embodiment, as shown in FIG. 18, the plurality of vias in the display panel provided in FIG. 6 may include at least a first via V1 to a ninth via V9 located in each sub-pixel of the display region AA and a tenth via V10 to a twenty-first via V21 located in the non-display region AA′.

In an exemplary manner, the quantity of any one of the tenth via V10 to the twenty-first V21 may be plural and any one of the tenth via V10 to the twenty-first V21 may be arranged in an array, which is not limited in the present disclosure.

In an exemplary embodiment, as shown in FIG. 18, the first via V1 to the thirteenth via V13 and the sixteenth via V16 in FIG. 18 have the same opening positions and connected structures as the first via V1 to the thirteenth via V13 and the sixteenth via V16 in FIG. 17.

In an exemplary embodiment, as shown in FIG. 18, an orthographic projection of the fourteenth via V14 on the substrate is within the range of an orthographic projection of the (2j−1)-th second scan signal line G2(2j−1) on the substrate, the third insulating layer within the fourteenth via V14 is removed to expose the surface of the (2j−1)-th second scan signal line G2(2j−1), and the fourteenth via V14 is configured to connect the subsequently formed third signal connection line to the (2j−1)-th second scan signal line G2(2j−1) through the via V14.

In an exemplary embodiment, as shown in FIG. 18, an orthographic projection of the fifteenth via V15 on the substrate is within the range of an orthographic projection of the second scan connection part of the 2j-th second scan signal line G2(2j) on the substrate, the third insulating layer within the fifteenth via V15 is removed to expose the surface of the second scan connection part of the 2j-th second scan signal line G2(2j), and the fifteenth via V15 is configured to connect the subsequently formed fourth signal connection line to the 2j-th second scan signal line G2(2j) through the via V15.

In an exemplary embodiment, as shown in FIG. 18, an orthographic projection of the seventeenth via V17 on the substrate is within the range of an orthographic projection of the (2j−1)-th light emitting signal line EM(2j−1) on the substrate, the third insulating layer within the seventeenth via V17 is removed to expose the surface of the (2j−1)-th light emitting signal line EM(2j−1), and the seventeenth via V17 is configured to connect the subsequently formed sixth signal connection line to the (2j−1)-th light emitting signal line EM(2j−1) through the via V17.

In an exemplary embodiment, as shown in FIG. 18, an orthographic projection of the eighteenth via V18 on the substrate is within the range of an orthographic projection of the second light emitting connection part of the 2j-th light emitting signal line EM(2j) on the substrate, the third insulating layer within the eighteenth via V18 is removed to expose the surface of the 2j-th light emitting signal line EM(2j), and the eighteenth via V18 is configured to connect the subsequently formed seventh signal connection line to the 2j-th light emitting signal line EM(2j) through the via V18.

In an exemplary embodiment, as shown in FIG. 18, an orthographic projection of the nineteenth via V19 on the substrate is within the range of an orthographic projection of the second signal connection line on the substrate, the third insulating layer within the nineteenth via V19 is removed to expose the surface of the second signal connection line, and the nineteenth via V19 is configured to connect the j-th second scan output line, the third connection signal line and the fourth connection signal line which are all formed subsequently to the second signal connection line through the via V19.

In an exemplary embodiment, as shown in FIG. 18, an orthographic projection of the twentieth via V20 on the substrate is within the range of an orthographic projection of the fifth signal connection line on the substrate, the third insulating layer within the twentieth via V20 is removed to expose the surface of the fifth signal connection line, and the twentieth via V20 is configured to connect the j-th light emitting output line, the sixth connection signal line and the seventh connection signal line which are formed subsequently to the fifth signal connection line through the via V20.

In an exemplary embodiment, as shown in FIG. 18, an orthographic projection of the twenty-first via V21 on the substrate is within the range of an orthographic projection of the reference power supply line on the substrate, the third insulating layer within the twenty-first via V21 is removed to expose the surface of the reference power supply line, and the twenty-first via V21 is configured to connect the subsequently formed reference output line to the reference power supply line through the via V21.

In an exemplary embodiment, as shown in FIG. 19, the plurality of vias in the display panel provided in FIG. 7 may include at least a first via V1 to a ninth via V9 located in each sub-pixel of the display region AA and a tenth via V10 to a nineteenth via V19 located in the non-display region AA′.

In an exemplary manner, the quantity of any one of the tenth via V10 to the nineteenth via V19 may be plural and any one of the tenth via V10 to the nineteenth via V19 may be arranged in an array, which is not limited in the present disclosure.

In an exemplary embodiment, as shown in FIG. 19, the first via V1 to the twelfth via V12, the seventeenth via V17, and the nineteenth via V19 in FIG. 19 have the same opening positions and connected structures as the first V1 via to the twelfth via V12, the seventeenth via V17, and the nineteenth via V19 in FIG. 17, respectively.

In an exemplary embodiment, as shown in FIG. 19, an orthographic projection of the thirteenth via V13 on the substrate is within the range of an orthographic projection of the second signal connection line on the substrate, the third insulating layer within the thirteenth via V13 is removed to expose the surface of the second signal connection line, and the thirteenth via V13 is configured to connect the subsequently formed 2j-th first scan output line to the second signal connection line through the via V13.

In an exemplary embodiment, as shown in FIG. 19, an orthographic projection of the fourteenth via V14 on the substrate is within the range of an orthographic projection of the second scan connection part of the (2j−1)-th second scan signal line G2(2j−1) on the substrate, the third insulating layer within the fourteenth via V14 is removed to expose the surface of the (2j−1)-th second scan signal line G2(2j−1), and the fourteenth via V14 is configured to connect the subsequently formed j-th second scan output line to the (2j−1)-th second scan signal line G2(2j−1) through the via V14.

In an exemplary embodiment, as shown in FIG. 19, an orthographic projection of the fifteenth via V15 on the substrate is within the range of an orthographic projection of the 2j-th second scan signal line G2(2j) on the substrate, the third insulating layer within the fifteenth via V15 is removed to expose the surface of the 2j-th second scan signal line G2(2j), and the fifteenth via V15 is configured to connect the j-th second scan output line and the second signal connection line which are formed subsequently to the 2j-th second scan signal line G2(2j) through the via V15.

In an exemplary embodiment, as shown in FIG. 19, an orthographic projection of the sixteenth via V16 on the substrate is within the range of an orthographic projection of the first signal connection line on the substrate, the third insulating layer within the sixteenth via V16 is removed to expose the surface of the first signal connection line, and the sixteenth via V16 is configured to connect the subsequently formed j-th third scan output line to the first signal connection line through the via V16.

In an exemplary embodiment, as shown in FIG. 19, an orthographic projection of the eighteenth via V18 on the substrate is within the range of an orthographic projection of the 2j-th light emitting signal line EM(2j) on the substrate, the third insulating layer within the eighteenth via V18 is removed to expose the surface of the 2j-th light emitting signal line EM(2j), and the eighteenth via V18 is configured to connect the subsequently formed j-th light emitting output line to the 2j-th light emitting signal line EM(2j) through the via V18.

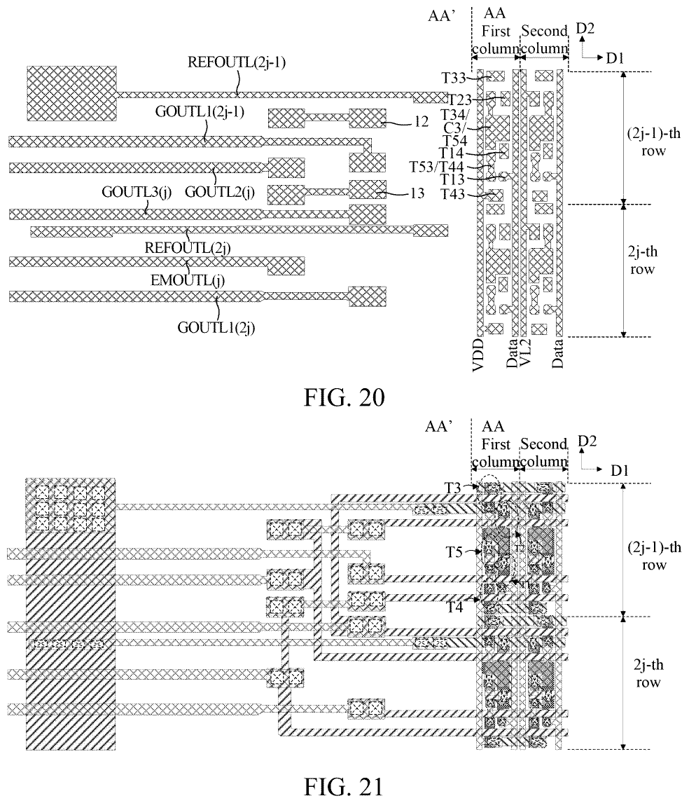

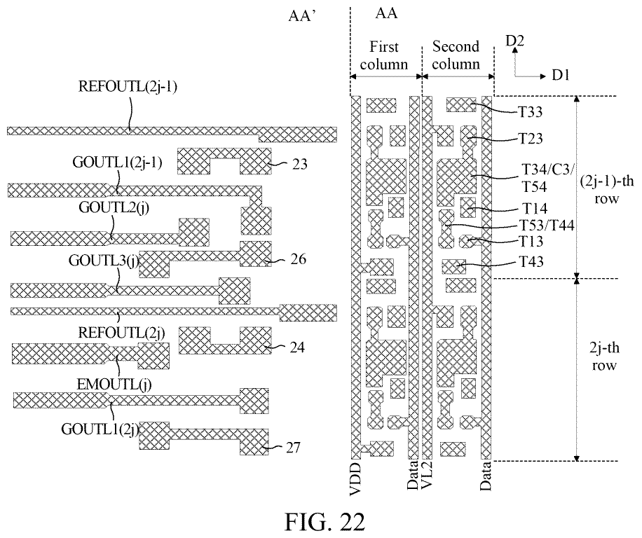

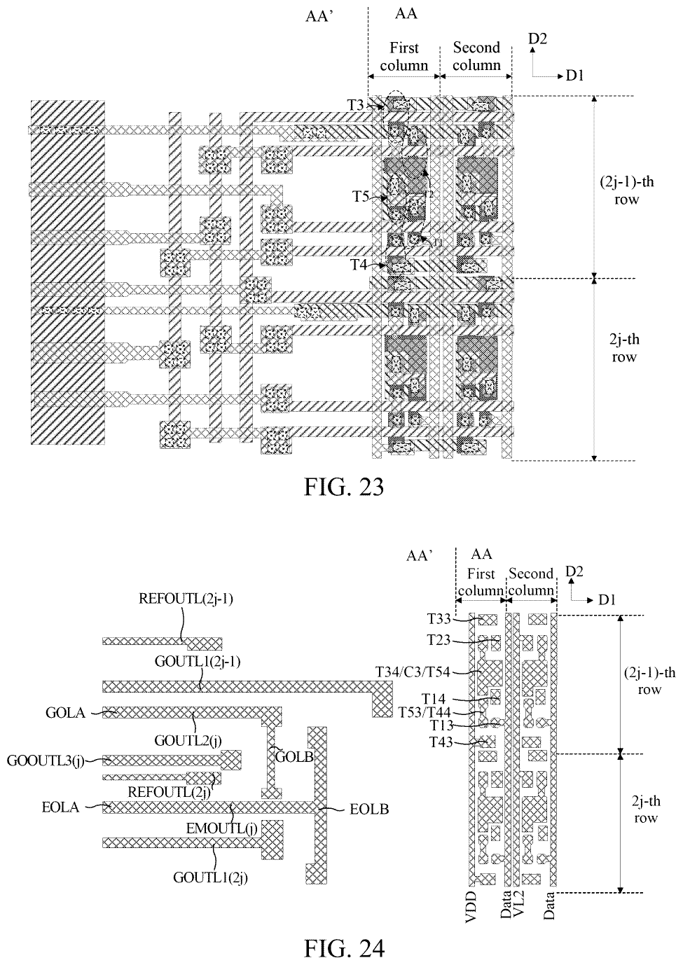

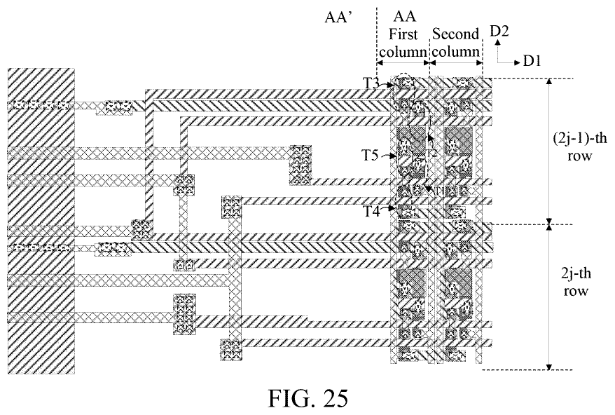

(5) A pattern of a second conductive layer is formed. In an exemplary embodiment, forming a pattern of a second conductive layer may include depositing a second conductive film on the substrate on which the above-mentioned patterns are formed, patterning the second conductive film using a patterning process to form a pattern of a second conductive layer on the third insulating layer, as shown in FIGS. 20 to 25, wherein FIG. 20 is a schematic diagram of a pattern of a second conductive layer of the display panel provided in FIG. 5, FIG. 21 is a schematic diagram of the display panel provided in FIG. 5 after a pattern of a second conductive layer is formed, FIG. 22 is a schematic view of a pattern of a second conductive layer of the display panel provided in FIG. 6, FIG. 23 is a schematic diagram of the display panel provided in FIG. 6 after a pattern of a second conductive layer is formed, FIG. 24 is a schematic diagram of a pattern of a second conductive layer of the display panel provided in FIG. 7 and FIG. 25 is a schematic diagram of the display panel provided in FIG. 7 after a pattern of a second conductive layer is formed. In an exemplary embodiment, the second conductive layer may be referred to as a Source Drain metal (SD) layer.

In an exemplary embodiment, as shown in FIGS. 20 to 25, the pattern of the second conductive layer may include at least a first electrode T13 and a second electrode T14 of the first transistor to a first electrode T53 and a second electrode T54 of the fifth transistor located in each sub-pixel of the display region, a third electrode plate C3 of the storage capacitor, a first power supply line VDD, a data signal line Data, and a second connection line VL2 located at least partially in the display region, and a first scan output line, a second scan output line, a third scan output line, a light emitting output line, and a reference output line located in the non-display region. FIGS. 20 to 25 show only the (2j−1)-th first scan output line GOUTL1(2j−1), the 2j-th first scan output line GOUTL1(2j), the j-th second scan output line GOUTL2(j), the j-th third scan output line GOUTL3(j), the j-th light emitting output line EMOUTL(j), the (2j−1)-th reference output line REFOUTL(2j−1) and the 2j-th reference output line REFOUTL(2j).

In an exemplary embodiment, the data signal line Data and the first power supply line VDD extend at least partially in the second direction VDD.

In an exemplary embodiment, the data signal line Data and a first electrode T13 of the first transistor are of an integral structure, and the first electrode T13 of the first transistor is electrically connected with the first area of the active layer of the first transistor through the first via.

In an exemplary embodiment, the first power supply line VDD and a first electrode T43 of a fourth transistor of the pixel drive circuit close to the first power supply line VDD are of an integral structure, and the first electrode T43 of the fourth transistor is connected with the first area of the active layer of the fourth transistor and the first connection line through the seventh via.

In an exemplary embodiment, a first electrode T43 of a fourth transistor of the pixel drive circuit away from the first power supply line VDD is provided separately, and the first electrode T43 of the fourth transistor is connected with the first area of the active layer of the fourth transistor and the first connection line through the seventh via. The first electrode T43 of the fourth transistor of the pixel drive circuit away from the first power supply line VDD is electrically connected with the first power supply line VDD through the first connection line and the first electrode T43 of the fourth transistor of the pixel drive circuit close to the first power supply line VDD.

In an exemplary embodiment, the first electrode of the second transistor may be provided separately or may be integrally formed with the second connection line VL2. The second connection line VL2 can form a mesh structure with the reference signal line, which can improve the uniformity of the reference signal.

In an exemplary embodiment, the second electrode T34 of the third transistor, the second electrode T54 of the fifth transistor and the third electrode C3 are of an integral structure, the second electrode T44 of the fourth transistor and the first electrode T53 of the fifth transistor are of an integral structure, and the second electrode T14 of the first transistor, the first electrode T23 of the second transistor and the first electrode T33 of the third transistor may be separately disposed.

In an exemplary embodiment, the second electrode T44 of the fourth transistor and the first electrode T53 of the fifth transistor are of an integral structure and extend in the second direction D2. The second electrode T14 of the first transistor and the first electrode T23 of the second transistor extend in the second direction D2. The first electrode T33 of the third transistor extends in the first direction D1.

In an exemplary embodiment, the second electrode T14 of the first transistor is electrically connected with the second area of the active layer of the first transistor and the control electrode of the fifth transistor through the second via, the first electrode T23 of the second transistor is electrically connected with the first area of the active layer of the second transistor and the reference signal line electrically connected with the sub-pixel through the third via, the first electrode T33 of the third transistor is electrically connected with the first area of the active layer of the third transistor and the initial signal line electrically connected with the sub-pixel through the fifth via. The second electrode T34 of the third transistor (also the second electrode T54 of the fifth transistor and the third electrode plate C3) is electrically connected with the second area of the active layer of the third transistor through the fourth via and electrically connected with the second area of the active layer of the fifth transistor and the first plate through the ninth via. The second electrode T44 of the fourth transistor (also the first electrode T53 of the fifth transistor) is electrically connected with the first area of the active layer of the fifth transistor through the eighth via, and is electrically connected with the second area of the active layer of the fourth transistor through the sixth via.

In an exemplary embodiment, the first scan output line, the second scan output line, the third scan output line, the light emitting output line and the reference output line extend at least partially along the first direction D1.

In an exemplary embodiment, as shown in FIGS. 20 and 21, the pattern of the second conductive layer may at least further include a second signal connection line 12 and a third signal connection line 13.

In an exemplary embodiment, the second signal connection line 12 and the third signal connection line 13 extend in the first direction D1.

In an exemplary embodiment, as shown in FIGS. 20 and 21, the distance between the boundary of the reference output line close to the display region and the display region is less than the distance between the boundary of the first scan output line close to the display region and the display region.

In an exemplary embodiment, as shown in FIGS. 20 and 21, the distance between the boundary of the second scan output line and the light emitting output line close to the display region and the display region is greater than the distance between the boundary of the first scan output line close to the display region and the display region.

In an exemplary embodiment, as shown in FIGS. 20 and 21, the distance between the boundary of the third scan output line, the second signal connection line 13, and the third signal connection line 13 close to the display region and the display region is equal to the distance between the boundary of the first scan output line close to the display region and the display region.

In an exemplary embodiment, as shown in FIGS. 20 and 21, an orthographic projection of the (2j−1)-th first scan output line GOUTL1(2j−1) on the substrate at least partially overlaps orthographic projections of the first signal connection line 11, the second scan connection part of the (2j−1)-th second scan signal line G2(2j) and the (2j−1)-th first scan signal line G1(2j−1) on the substrate, respectively, and the (2j−1)-th first scan output line GOUTL1(2j−1) is electrically connected with the (2j−1)-th first scan signal line G1(2j−1) through the twelfth via.

In an exemplary embodiment, as shown in FIGS. 20 and 21, an orthographic projection of the 2j-th first scan output line GOUTL1(2j) on the substrate at least partially overlaps orthographic projections of the second light emitting connection part of the 2j-th light emitting signal line EM(2j) and the 2j-th first scan signal line G1(2j) on the substrate, respectively, and the 2j-th first scan output line GOUTL1(2j) is electrically connected with the 2j-th first scan signal line G1(2j) through the thirteenth via.

In an exemplary embodiment, as shown in FIGS. 20 and 21, an orthographic projection of the j-th third scan output line GOUTL3(j) on the substrate at least partially overlaps an orthographic projection of the 2j-th third scan signal line G3(2j) on the substrate, and the j-th third scan output line GOUTL3(j) is electrically connected with the 2j-th third scan signal line G3(2j) through the sixteenth via. In an exemplary embodiment, the j-th third scan output line GOUTL3(j) is electrically connected with the (2j−1)-th third scan signal line G3(2j−1) through the 2j-th third scan signal line G3(2j) and the first signal connection line 11.

In an exemplary embodiment, as shown in FIGS. 20 and 21, an orthographic projection of the second scan connection part on the substrate at least partially overlaps orthographic projections of the (2j−1)-th first scan output line GOUTL1(2j−1), the j-th second scan output line GOUTL2(j), the j-th third scan output line GOUTL3(j) and the second signal connection line 12 on the substrate, and the second scan connection part is electrically connected with the j-th second scan output line GOUTL2(j) and the second signal connection line 12, respectively, through the fifteenth via.

In an exemplary embodiment, as shown in FIGS. 20 and 21, an orthographic projection of the second signal connection line 12 on the substrate at least partially overlaps orthographic projections of the (2j−1)-th second scan signal line G2(2j−1) and the first signal connection line 11 on the substrate, and the second signal connection line 12 is electrically connected with the (2j−1)-th second scan signal line G2(2j−1) through the fourteenth via.

In an exemplary embodiment, as shown in FIGS. 20 and 21, an orthographic projection of the second light emitting connection part EMB on the substrate at least partially overlaps orthographic projections of the j-th light emitting output line EMOUTL(j), the j-th third scan output line GOUTL3(j), the 2j-th first scan output line GOUTL1(2j) and the third signal connection line 13 on the substrate, and the second light emitting connection part EMB is electrically connected with the j-th light emitting output line EMOUTL(j) and the third signal connection line 13, respectively, through an eighteenth via.

In an exemplary embodiment, as shown in FIGS. 20 and 21, an orthographic projection of the third signal connection line 13 on the substrate at least partially overlaps orthographic projections of the (2j−1)-th light emitting signal line EM(2j−1), the first signal connection line 11 and the second scan connection part G2B on the substrate, and the third signal connection line 13 is electrically connected with the (2j−1)-th light emitting signal line EM(2j−1) through the seventeenth via. The j-th light emitting output line EMOUTL(j) is electrically connected with the (2j−1)-th light emitting signal line EM(2j−1) through the second light emitting connection part EMB and the third signal connection line 13.

In an exemplary embodiment, the length of the second light emitting connection part in the first direction D1 is greater than the length of the first light emitting connection part in the second direction D2.

In an exemplary embodiment, as shown in FIGS. 20 and 21, an orthographic projection of the (2j−1)-th reference output line REFOUTL(2j−1) on the substrate at least partially overlaps orthographic projections of the first signal connection line 11 and the (2j−1)-th reference signal line REF(2j−1) on the substrate, and the (2j−1)-th reference output line REFOUTL(2j−1) is electrically connected with the (2j−1)-th reference signal line REF(2j−1) through the tenth via and with the reference power supply line through the nineteenth via.

In an exemplary embodiment, as shown in FIGS. 20 and 21, an orthographic projection of the 2j-th reference output line REFOUTL(2j) on the substrate at least partially overlaps orthographic projections of the second scan connection part G2B, the second light emitting connection part and the 2j-th reference signal line REF(2j) on the substrate, and the 2j-th reference output line REFOUTL(2j) is electrically connected with the 2j-th reference output line REFOUTL(2j) through the eleventh via and with the reference power supply line through the nineteenth via.

In an exemplary embodiment, as shown in FIGS. 22 and 23, the pattern of the second conductive layer may at least further include a third signal connection line 23, a fourth signal connection line 24, a sixth signal connection line 26, and a seventh signal connection line 27.

In an exemplary embodiment, the third signal connection line 23, the fourth signal connection line 24, the sixth signal connection line 26 and the seventh signal connection line 27 may extend in the first direction D1.

In an exemplary embodiment, as shown in FIGS. 22 and 23, the distance between the boundary of the reference output line close to the display region and the display region is less than the distance between the boundary of the first scan output line close to the display region and the display region.

In an exemplary embodiment, as shown in FIGS. 22 and 23, the distance between the boundary of the second scan output line, the third scan output line and the light emitting output line close to the display region and the display region is greater than the distance between the boundary of the first scan output line close to the display region and the display region, and the distance between the boundary of the third scan output line close to the display region and the display region is less than the distance between the boundary of the second scan output line and the light emitting output line close to the display region and the display region.

In an exemplary embodiment, as shown in FIGS. 22 and 23, the distance between the boundary of the third signal connection line 23, the fourth signal connection line 24, the sixth signal connection line 26, and the seventh signal connection line 27 close to the display region and the display region is equal to the distance between the boundary of the first scan output line close to the display region and the display region.

In an exemplary embodiment, as shown in FIGS. 22 and 23, an orthographic projection of the (2j−1)-th first scan output line GOUTL1(2j−1) on the substrate at least partially overlaps orthographic projections of the first signal connection line 21, the second signal connection line 22, the fifth signal connection line 25 and the (2j−1)-th first scan signal line G1(2j−1) on the substrate, respectively, and the (2j−1)-th first scan output line GOUTL1(2j−1) is electrically connected with the (2j−1)-th first scan signal line G1(2j−1) through the twelfth via.

In an exemplary embodiment, as shown in FIGS. 22 and 23, an orthographic projection of the 2j-th first scan output line GOUTL1(2j) on the substrate at least partially overlaps orthographic projections of the first signal connection line 21, the second signal connection line 22, the fifth signal connection line 25 and the 2j-th first scan signal line G1(2j) on the substrate, respectively, and 2j-th first scan output line GOUTL1(2j) is electrically connected with the 2j-th first scan signal line G1(2j) through the thirteenth via.

In an exemplary embodiment, as shown in FIGS. 22 and 23, an orthographic projection of the j-th third scan output line GOUTL3(j) on the substrate at least partially overlaps an orthographic projection of the 2j-th third scan signal line G3(2j) on the substrate, and the j-th third scan output line GOUTL3(j) is electrically connected with the 2j-th third scan signal line G3(2j) through the sixteenth via. The j-th third scan output line GOUTL3(j) is electrically connected with the (2j−1)-th third scan signal line G3(2j−1) through the 2j-th third scan signal line G3(2j) and the first signal connection line.

In an exemplary embodiment, as shown in FIGS. 22 and 23, an orthographic projection of the second signal connection line 22 on the substrate at least partially overlaps orthographic projections of the (2j−1)-th first scan output line GOUTL1(2j−1), the 2j-th first scan output line GOUTL1(2j), the j-th second scan output line GOUTL2(j), the j-th third scan output line GOUTL3(j), the third signal connection line 23 and the fourth signal connection line 24 on the substrate, and the second signal connection line 22 is electrically connected with the j-th second scan output line GOUTL2(j), the third signal connection line 23 and the fourth signal connection line 24 through nineteenth via, respectively.

In an exemplary embodiment, as shown in FIGS. 22 and 23, an orthographic projection of the third signal connection line 23 on the substrate is electrically connected with the first signal connection line 21 and the (2j−1)-th second scan signal line G2(2j−1), and the third signal connection line 23 is electrically connected with the (2j−1)-th second scan signal line G2(2j−1) through the fourteenth via. The j-th second scan output line GOUTL2(j) is electrically connected with the (2j−1)-th second scan signal line G2(2j−1) through the second signal connection line 22 and the third signal connection line 23.

In an exemplary embodiment, as shown in FIGS. 22 and 23, an orthographic projection of the fourth signal connection line 24 on the substrate is electrically connected with the first signal connection line 21 and the 2j-th second scan signal line G2(2j), and the fourth signal connection line 24 is electrically connected with the 2j-th second scan signal line G2(2j) through the fifteenth via. The j-th second scan output line GOUTL2(j) is electrically connected with the (2j−1)-th second scan signal line G2(2j) through the second signal connection line 22 and the fourth signal connection line 24.

In an exemplary embodiment, as shown in FIGS. 22 and 23, an orthographic projection of the fifth signal connection line 25 on the substrate at least partially overlaps orthographic projections of the (2j−1)-th first scan output line GOUTL1(2j−1), the 2j-th first scan output line GOUTL1(2j), the j-th second scan output line GOUTL2(j), the j-th third scan output line GOUTL3(j), the j-th light emitting output line EMOUTL(j), the sixth signal connection line 26 and the seventh signal connection line 27 on the substrate, and the fifth signal connection line 25 is electrically connected with the j-th light emitting output line EMOUTL(j), the sixth signal connection line 26 and the seventh signal connection line 27, respectively, through the twentieth via.

In an exemplary embodiment, as shown in FIGS. 22 and 23, an orthographic projection of the sixth signal connection line 26 on the substrate at least partially overlaps orthographic projections of the first signal connection line 21, the second signal connection line 22 and the (2j−1)-th light emitting signal line EM(2j−1) on the substrate, and the sixth signal connection line 26 is electrically connected with the (2j−1)-th light emitting signal line EM(2j−1) through the seventeenth via.

In an exemplary embodiment, as shown in FIGS. 22 and 23, an orthographic projection of the seventh signal connection line 27 on the substrate is at least partially overlapped with orthographic projections of the first signal connection line 21, the second signal connection line 22, and the 2j-th light emitting signal line EM(2j) on the substrate, and the seventh signal connection line 27 is electrically connected with the 2j-th light emitting signal line EM(2j) through the eighteenth via.

In an exemplary embodiment, as shown in FIGS. 22 and 23, an orthographic projection of the (2j−1)-th reference output line REFOUTL(2j−1) on the substrate at least partially overlaps orthographic projections of the first signal connection line 21, the second signal connection line 22, the fifth signal connection line 25 and the (2j−1)-th reference signal line REF(2j−1) on the substrate, and the (2j−1)-th reference output line REFOUTL(2j−1) is electrically connected with the (2j−1)-th reference signal line REF(2j−1) through the tenth via and with the reference power supply line through the twenty-first via.

In an exemplary embodiment, as shown in FIGS. 22 and 23, an orthographic projection of the 2j-th reference output line REFOUTL(2j) on the substrate at least partially overlaps orthographic projections of the first signal connection line 21, the second signal connection line 22, the fifth signal connection line 25 and the 2j-th reference signal line REF(2j) on the substrate, and the 2j-th reference output line REFOUTL(2j) is electrically connected with the 2j-th reference output line REFOUTL(2j) through the eighteenth via and with the reference power supply line through the twenty-first via.

In an exemplary embodiment, as shown in FIGS. 24 and 25, the j-th second scan output line GOUTL2(j) includes a first scan output connection part GOLA extending in the first direction D1 and a second scan output connection part GOLB extending in the second direction D2 which are connected with each other, a virtual straight line extending in the second direction D2 passes through the second scan connection part G2D and the second scan output connection part GOLB, and the second scan connection part is located on a side of the first signal connection line close to the display region AA.

In an exemplary embodiment, as shown in FIGS. 24 and 25, the j-th light emitting output line EMOUTL(j) includes a first light emitting output connection part EOLA extending in the first direction D1 and a second light emitting output connection part EOLB extending in the second direction D2, which are connected with each other; the second light emitting output connection part EOLB is located on a side of the second scan output connection part GOLB close to the display region AA.

In an exemplary embodiment, as shown in FIGS. 24 and 25, the distance between the boundary of the reference output line close to the display region and the display region is greater than the distance between the boundary of the first scan output line close to the display region and the display region.

In an exemplary embodiment, as shown in FIGS. 24 and 25, the distance between the boundary of the (2j−1)-th first scan output line GOUTL1(2j−1) close to the display region and the display region is less than the distance between the boundary of the j-th light emitting output line EMOUTL(j) close to the display region and the display region, the distance between the boundary of the j-th light emitting output line EMOUTL(j) close to the display region and the display region is less than the distance between the boundary of the 2j-th first scan output line GOUTL1(2j) and the j-th second scan output line GOUTL2(j) close to the display region and the display region, and the distance between the boundary of the j-th second scan output line GOUTL2(j) close to the display region and the display region is less than the distance between the boundary of the j-th third scan output line GOUTL3(j) close to the display region and the display region, the distance between the boundary of the j-th third scan output line GOUTL3(j) close to the display region and the display region is less than the distance between the boundary of the reference output line close to the display region and the display region.

In an exemplary embodiment, as shown in FIGS. 24 and 25, an orthographic projection of the (2j−1)-th first scan output line GOUTL1(2j−1) on the substrate at least partially overlaps orthographic projections of the first signal connection line 21, the second scan connection part of the (2j−1)-th second scan signal line G2(2j−1) and the (2j−1)-th first scan signal line G1(2j−1) on the substrate, respectively, and the (2j−1)-th first scan output line GOUTL1(2j−1) is electrically connected with the (2j−1)-th first scan signal line G1(2j−1) through the twelfth via.

In an exemplary embodiment, as shown in FIGS. 24 and 25, an orthographic projection of the 2j-th first scan output line GOUTL1(2j) on the substrate at least partially overlaps an orthographic projection of the second signal connection line 32 on the substrate, and 2j-th first scan output line GOUTL1(2j) is electrically connected with the second signal connection line 32 through the thirteenth via.

In an exemplary embodiment, as shown in FIGS. 24 and 25, an orthographic projection of the first signal connection line 31 on the substrate at least partially overlaps orthographic projections of the (2j−1)-th first scan output line GOUTL1(2j−1), the j-th second scan output line GOUTL2(j) and the j-th third scan output line GOUTL3(j) on the substrate, and the first signal connection line 31 is electrically connected with the j-th third scan output line GOUTL3(j) through the sixteenth via. The j-th third scan output line GOUTL3(j) is electrically connected with the (2j−1)-th third scan signal line G3(2j−1) and the 2j-th third scan signal line G3(2j) through the first signal connection line 31, respectively.

In an exemplary embodiment, as shown in FIGS. 24 and 25, an orthographic projection of the second scan connection part on the substrate at least partially overlaps orthographic projections of the (2j−1)-th first scan output line GOUTL1(2j−1) and the first scan output connection part GOLA on the substrate, and the second scan connection part is electrically connected with the first scan output connection part GOLA through the fourteenth via.

In an exemplary embodiment, as shown in FIGS. 24 and 25, an orthographic projection of the second scan output connection part GOLB on the substrate at least partially overlaps an orthographic projection of the 2j-th third scan signal line G3(2j) and the 2j-th second scan signal line G2(2j) on the substrate, and the second scan output connection part GOLB is electrically connected with the 2j-th second scan signal line G2(2j) through the fifteenth via.

In an exemplary embodiment, as shown in FIGS. 24 and 25, an orthographic projection of the second signal connection line 32 on the substrate at least partially overlaps an orthographic projection of the 2j-th first scan output line GOUTL1(2j) on the substrate, and the second signal connection line 32 is electrically connected with the 2j-th first scan output line GOUTL1(2j) and the 2j-th first scan signal line G1(2j), respectively.

In an exemplary embodiment, as shown in FIGS. 24 and 25, the length of the second signal connection line 32 in the second direction D2 is greater than the length of the first scan signal line in the second direction D2.

In an exemplary embodiment, as shown in FIGS. 24 and 25, an orthographic projection of the second light emitting output connection part EOLB on the substrate at least partially overlaps orthographic projections of the second signal connection line 32, the (2j−1)-th light emitting signal line EM(2j−1), the 2j-th light emitting signal line EM(2j), the 2j-th third scan signal line G3(2j) and the 2j-th second scan signal line G2(2j) on the substrate, and the second light emitting output connection part is electrically connected with the (2j−1)-th light emitting signal line EM(2j−1) through the seventeenth via and electrically connected with the 2j-th light emitting signal line EM(2j) through the eighteenth via, respectively.

In an exemplary embodiment, as shown in FIGS. 24 and 25, an orthographic projection of the (2j−1)-th reference output line REFOUTL(2j−1) on the substrate at least partially overlaps an orthographic projection of the (2j−1)-th reference signal line REF(2j−1) on the substrate, and the (2j−1)-th reference output line REFOUTL(2j−1) is electrically connected with the (2j−1)-th reference signal line REF(2j−1) through the tenth via and electrically connected with the reference power supply line through the nineteenth via.

In an exemplary embodiment, as shown in FIGS. 24 and 25, an orthographic projection of the 2j-th reference output line REFOUTL(2j) on the substrate at least partially overlaps an orthographic projection of the 2j-th reference signal line REF(2j) on the substrate, and the 2j-th reference output line REFOUTL(2j) is electrically connected with the 2j-th reference output line REFOUTL(2j) through the tenth via and electrically connected with the reference power supply line through the nineteenth via.

(6) A pattern of a planarization layer is formed. In an exemplary embodiment, forming a pattern of a planarization layer may include depositing a fourth insulating film on the substrate on which the above-mentioned patterns are formed, patterning the fourth insulating film using a patterning process to form a fourth insulating layer covering the second conductive layer, coating a planarization film on the fourth insulating layer, patterning the planarization film using a patterning process to form a pattern of a planarization layer covering the fourth insulating layer.

In an exemplary embodiment, the fourth insulating layer and the planarization layer are provided with a via exposing the second electrode of the fifth transistor (also the second electrode of the third transistor and the third electrode plate), the via is configured to connect a subsequently formed anode to the second electrode of the fifth transistor (also the second electrode of the third transistor and the third electrode plate).

So far, the drive circuit layer is prepared on the substrate. In a plane parallel to the display panel, the drive circuit layer may include a plurality of circuit units, each of which may include a pixel drive circuit connected with a first scan signal line, a second scan signal line, a third scan signal line, a light emitting signal line, an initial signal line, a reference signal line, a data signal line, and a first power supply line. In a plane perpendicular to the display panel, the drive circuit layer may be disposed on the substrate.

The drive circuit layer may include a shielding layer, a first insulating layer, a semiconductor layer, a second insulating layer, a first conductive layer, a third insulating layer, a second conductive layer, and a planarization layer that are sequentially disposed on the substrate. The shielding layer may at least include a reference signal line, an initial signal line and a first electrode plate of the storage capacitor, the semiconductor layer may at least include active layers of the first transistor to the fifth transistor and a second electrode plate of the storage capacitor, the first conductive layer may at least include gate electrodes of the first transistor to the seventh transistor, a first scan signal line, a second scan signal line, a third scan signal line, a light emitting signal line and a reference power supply line, and the second conductive layer may at least include a data signal line, a first power supply line, first and second electrodes of a plurality of transistors, a third electrode plate of the storage capacitor, a first scan output line, a second scan output line, a third scan output line, a light emitting output line and a reference output line.

In an exemplary embodiment, the first conductive layer and the second conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo.

In an exemplary embodiment, the first insulating layer, the second insulating layer, the third insulating layer, and the fourth insulating layer may be made of any one or more of silicon oxide (SiOx), silicon nitride (SiNx), and silicon oxynitride (SiON), and may be single layer, multi-layer, or composite layers. The first insulating layer may be referred to as a Buffer layer, the second insulating layer may be referred to as a gate insulating (GI) layer, the third insulating layer may be referred to as an interlayer insulating (ILD) layer, the fourth insulating layer may be a passivation (PVX) layer, and the planarization layer may be made of an organic material, such as a resin, etc.

In an exemplary embodiment, after preparation of the drive circuit layer is completed, a light emitting structure layer is prepared on the drive circuit layer, and a preparation process of the light emitting structure layer may include following operations.

(7) A pattern of an anode conductive layer is formed. In an exemplary embodiment, forming a pattern of an anode conductive layer may include depositing an anode conductive film on the substrate on which the above-mentioned patterns are formed, patterning the anode conductive film using a patterning process to form an anode conductive layer disposed on a second planarization layer, the anode conductive layer includes at least a plurality of anode patterns.

In an exemplary embodiment, the anode conductive layer adopts a single-layer structure, such as indium tin oxide ITO or indium zinc oxide IZO, or may adopt a multi-layer composite structure, such as ITO/Ag/ITO, etc.

In an exemplary embodiment, the plurality of anode patterns may include a first anode of a red light emitting device, a second anode of a blue light emitting device, a third anode of a first green light emitting device, and a fourth anode of a second green light emitting device. The first anode may be located at a red sub-pixel emitting red light, the second anode may be located at a blue sub-pixel emitting blue light, the third anode may be located at a first green sub-pixel emitting green light, and the fourth anode may be located at a second green sub-pixel emitting green light.

In an exemplary embodiment, the first anode and the second anode may be sequentially disposed along the first direction, the third anode and the fourth anode may be sequentially disposed along the first direction, and the third anode and the fourth anode may be disposed on a side of the first anode and the second anode in the second direction. Alternatively, the first anode and the second anode may be sequentially disposed along the second direction, the third anode and the fourth anode may be sequentially disposed along the second direction Y, and the third anode and the fourth anode may be disposed on a side of the first anode and the second anode in the first direction X.

In an exemplary embodiment, the first anode, the second anode, the third anode, and the fourth anode may be respectively connected with the second electrode of the drive transistor of the sub-pixel in which they are located through an anode via, and the anode shapes and areas of the four sub-pixels in a pixel unit may be the same or may be different.

In an exemplary embodiment, at least one of the first anode, the second anode, the third anode, and the fourth anode may include an anode body part and an anode connection part connected with each other.

In an exemplary embodiment, the first anode may include a first anode body part and a first anode connection part connected with each other, the first anode body part may have a rectangular shape, the corner portion of the rectangular shape may be provided with an arc-shaped chamfer. In an exemplary embodiment, the second anode may include a second anode body part and a second anode connection part connected with each other, the second anode body part may have a rectangular shape, the corner portion of the rectangular shape may be provided with an arc-shaped chamfer, and the second anode connection part may have a shape of a strip. In an exemplary embodiment, the third anode may include a third anode body part and a third anode connection part connected with each other, the third anode body part may have a rectangular shape, the corner portion of the rectangular shape may be provided with an arc-shaped chamfer, and the third anode connection part may have a shape of a strip. In an exemplary embodiment, the fourth anode may include a fourth anode body part and a fourth anode connection part connected with each other, the fourth anode body part have a rectangular shape, the corner portion of the rectangular shape may be provided with an arc-shaped chamfer, and the fourth anode connection part may have a shape of a strip.

(8) A pattern of a pixel definition layer is formed. In an exemplary embodiment, forming a pattern of a pixel definition layer may include coating a pixel definition film on the substrate on which the above-mentioned patterns are formed, patterning the pixel definition film using a patterning process to form a pixel definition layer, wherein a pixel opening is provided on the pixel definition layer of each sub-pixel, the pixel definition film in the pixel opening is removed to expose the anode of the sub-pixel where the pixel opening is located.

In an exemplary implementation, an orthographic projection of the pixel opening on the substrate is not overlapped with an orthographic projection of the anode via on the substrate.

In an exemplary implementation, in at least one sub-pixel, a second distance between an edge of a side of the pixel opening close to the anode via side and an edge of a side of the anode via close to the pixel opening may be greater than or equal to 3.0 μm, and the second distance may be a minimum distance between the pixel opening and the anode via. For example, in at least one sub-pixel, the second distance between the pixel opening and the anode via may be about 7.88 μm. Because the anode via is a via penetrating through the planarization layer, by disposing the pixel opening beyond the predefined distance of the anode via in the present disclosure, the planarization of the anode in the pixel opening may be ensured, the planarization of the pixel and the display quality may be improved.

In an exemplary embodiment, a subsequent preparation process may include: forming an organic emitting layer using an evaporation process and inkjet printing process at first, then forming a cathode on the organic emitting layer, and then forming an encapsulation structure layer, wherein the encapsulation structure layer may include a first encapsulation layer, a second encapsulation layer, and a third encapsulation layer which are stacked, the first encapsulation layer and the third encapsulation layer may be made of an inorganic material, the second encapsulation layer may be made of an organic material, and the second encapsulation layer is arranged between the first encapsulation layer and the third encapsulation layer, which may ensure that external water vapor cannot enter the light emitting structure layer.

The structure shown and mentioned above in the present disclosure and the manufacturing process thereof are merely an exemplary description. In an exemplary implementation, the corresponding structures may be altered and the patterning processes may be added or reduced according to actual needs. For example, a part of lapping vias may be disposed in sub-pixels away from the first center line, so as to increase the spacing between adjacent lapping vias, reduce mutual interference, and ensure that no crosstalk is in the display screen, which is not limited in the present disclosure.

In an exemplary embodiment, the display panel of the present disclosure may be applied to other display devices having pixel drive circuits, such as quantum-dot displays and the like, which is not limited in the present disclosure.

The present disclosure further provides a display apparatus which includes the aforementioned display panel. The display apparatus may be any product or component with a display function, such as a mobile phone, a tablet computer, a television, a display, a laptop computer, a digital photo frame, or a navigator, and the embodiments of the present invention are not limited thereto.

The drawings of the embodiments of the present disclosure only involve structures involved in the embodiments of the present disclosure, and other structures may refer to usual designs.

For the sake of clarity, the thickness and size of a layer or a micro structure is enlarged in the accompanying drawings used to describe the embodiments of the present disclosure. It can be understood that when an element such as a layer, film, region or substrate is described as being “on” or “under” another element, this element may be “directly” located “on” or “under” the another element, or an intermediate element may exist.

Although the implementations disclosed in the present disclosure are as above, the described contents are only implementations used for convenience of understanding the present disclosure and are not intended to limit the present disclosure. Any skilled person in the art to which the present invention pertains can make any modifications and alterations in forms and details of implementations without departing from the spirit and scope of the present disclosure. However, the patent protection scope of the present disclosure should be subject to the scope defined by the appended claims.

1. A display panel, comprising: a substrate and a drive circuit layer disposed on the substrate, wherein:
the substrate comprises a display region and a non-display region, the drive circuit layer comprises: a plurality of pixel drive circuits disposed in the display region and a plurality of first scan signal lines disposed in the display region and the non-display region, the first scan signal lines are extended at least partially in a first direction, the pixel drive circuits are electrically connected with the first scan signal lines, and the first scan signal lines connected with adjacent rows of pixel drive circuits are electrically isolated;
the drive circuit layer further comprises first signal lines located in the non-display region and second signal lines corresponding to the first signal lines, the first signal lines are electrically connected with the first scan signal lines and configured to provide a signal to the first scan signal line, an orthographic projection of a first signal line on the substrate is at least partially overlapped with an orthographic projection of a corresponding second signal line on the substrate; and
a resistance of the first signal lines electrically connected to adjacent first scan signal lines are substantially equal and/or a capacitance value between the first signal lines electrically connected to adjacent first scan signal lines and corresponding second signal lines are substantially equal.

2. The display panel according to claim 1, wherein:
the drive circuit layer further comprises: a plurality of second scan signal lines, a plurality of third scan signal lines, a plurality of light emitting signal lines, and a plurality of reference signal lines disposed in the display region and the non-display region, the pixel drive circuits are electrically connected with the second scan signal lines, the third scan signal lines, the light emitting signal lines, and the reference signal lines, respectively, the second scan signal lines, the third scan signal lines, the light emitting signal lines, and the reference signal lines extend at least partially in the first direction;
an i-th row of pixel drive circuits are electrically connected to an i-th first scan signal line, an i-th second scan signal line, an i-th third scan signal line, an i-th light emitting signal line, and an i-th reference signal line, respectively, 1≤i≤M, and M is a total number of rows of the pixel drive circuits;
the i-th third scan signal line, the i-th reference signal line, the i-th second scan signal line, the i-th first scan signal line and the i-th light emitting signal line are arranged sequentially along a second direction, the i-th third scan signal line is located on a side of the i-th reference signal line close to an (i−1)-th light emitting signal line, the i-th light emitting signal line is located on a side of the i-th first scan signal line close to an (i+1)-th third scan signal line, and the second direction is intersected with the first direction; and
the second signal line is electrically connected with at least one of the second scan signal line, the third scan signal line, and the light emitting signal line.

3. The display panel according to claim 2, wherein:
the drive circuit layer further comprises: M first scan output lines, M/2 second scan output lines, M/2 third scan output lines, M reference output lines and M/2 light emitting output lines located in the non-display region, the first scan output lines, the second scan output lines, the third scan output lines, the reference output lines and the light emitting output lines are extended at least partially in the first direction;
an i-th first scan output line is electrically connected with an i-th first scan signal line, an i-th reference output line is electrically connected with the i-th reference signal line, a j-th second scan output line is electrically connected with a (2j−1)-th second scan signal line and a 2j-th second scan signal line respectively, a j-th third scan output line is electrically connected with a (2j−1)-th third scan signal line and a 2j-th third scan signal line respectively, a j-th light emitting output line is electrically connected with a (2j−1)-th light emitting signal line and a 2j-th light emitting signal line respectively, 1≤j≤M/2; and
a (2j−1)-th reference output line, a (2j−1)-th first scan output line, the j-th second scan output line, the j-th third scan output line, a 2j-th reference output line, the j-th light emitting output line and a 2j-th first scan output line are sequentially arranged in the second direction.

4. The display panel according to claim 3, wherein:
the drive circuit layer further comprises: a reference power supply line located in the non-display region and a data signal line and a first power supply line located at least partially in the display region, the reference power supply line, the data signal line and the first power supply line are extended at least partially in the second direction; and
the pixel drive circuit is electrically connected with the data signal line and the first power supply line, respectively, and an orthographic projection of the reference power supply line on the substrate is at least partially overlapped with an orthographic projection of the reference output line on the substrate, and the reference power supply line is electrically connected with the reference output line.

5. The display panel according to claim 4, wherein:
the drive circuit layer comprises: a first conductive layer and a second conductive layer sequentially stacked on the substrate;
the first conductive layer at least comprises the first scan signal line, the second scan signal line, the third scan signal line, the light emitting signal line and the reference power supply line; and
the second conductive layer at least comprises the first scan output line, the second scan output line, the third scan output line, the reference output line, the light emitting output line, the data signal line and the first power supply line.

6. The display panel according to claim 5, wherein the first conductive layer and the second conductive layer have substantially equal square resistance.

7. The display panel according to claim 6, wherein the first conductive layer and the second conductive layer are made of a same material and thickness.

8. The display panel according to claim 6, wherein distances between boundaries of the first signal lines electrically connected to the adjacent first scan signal lines close to the display region and the display region are substantially equal, and average lengths of the first signal lines electrically connected to the adjacent first scan signal lines in the second direction are substantially equal.

9. The display panel according to claim 8, wherein areas of overlapping regions between the first signal lines electrically connected to the adjacent first scan signal lines and the corresponding second signal lines are substantially equal.

10. The display panel according to claim 5, wherein:
the drive circuit layer further comprises: a first signal connection line located in the first conductive layer, the first signal connection line is extended in the second direction and electrically connected with the (2j−1)-th third scan signal line and the 2j-th third scan signal line, respectively;
an orthographic projection of the first signal connection line on the substrate is at least partially overlapped with an orthographic projection of the (2j−1)-th first scan output line on the substrate; and
an orthographic projection of the j-th third scan output line on the substrate is at least partially overlapped with an orthographic projection of the 2j-th third scan signal line on the substrate, and the j-th third scan output line is electrically connected with the 2j-th third scan signal line.

11. The display panel according to claim 10, wherein:
the drive circuit layer further comprises: a second signal connection line located in the second conductive layer, the second signal connection line is extended in the first direction;
the 2j-th second scan signal line comprises a first scan connection part and a second scan connection part connected with each other, wherein the first scan connection part is extended in the first direction, the second scan connection part is extended in the second direction, and the first signal connection line is located on a side of the second scan connection part close to the display region;
an orthographic projection of the second scan connection part on the substrate is at least partially overlapped with orthographic projections of the (2j−1)-th first scan output line, the j-th second scan output line, the j-th third scan output line and the second signal connection line on the substrate, and the second scan connection part is electrically connected with the j-th second scan output line and the second signal connection line, respectively; and
an orthographic projection of the second signal connection line on the substrate is at least partially overlapped with orthographic projections of the (2j−1)-th second scan signal line and the first signal connection line on the substrate, and the second signal connection line is electrically connected with the (2j−1)-th second scan signal line.

12. The display panel according to claim 11, wherein:
the drive circuit layer further comprises: a third signal connection line located in the second conductive layer, the third signal connection line is extended in the first direction;
the 2j-th light emitting signal line comprises a first light emitting connection part and a second light emitting connection part connected with each other, wherein the first light emitting connection part is extended in the first direction, the second light emitting connection part is extended in the second direction, and the second light emitting connection part is located between the reference power supply line and the second scan connection part;
an orthographic projection of the second light emitting connection part on the substrate is at least partially overlapped with orthographic projections of the j-th light emitting output line, the j-th third scan output line, the 2j-th first scan output line and the third signal connection line on the substrate, and the second light emitting connection part is electrically connected with the j-th light emitting output line and the third signal connection line, respectively;
an orthographic projection of the third signal connection line on the substrate is at least partially overlapped with orthographic projections of the (2j−1)-th light emitting signal line, the first signal connection line and the second scan connection part on the substrate and the third signal connection line is electrically connected with the (2j−1)-th light emitting signal line; and
a length of an overlapping region of the second light emitting connection part and the 2j-th first scan output line along the first direction is greater than a length of the first light emitting connection part along the second direction.

13. The display panel according to claim 12, wherein:
the first signal lines electrically connected with the i-th first scan signal line comprises: the i-th first scan output line; and
the second signal lines corresponding to the first signal lines electrically connected with a (2j−1)-th first scan signal line comprise the first signal connection line and the 2j-th second scan signal line, and the second signal lines corresponding to the first signal lines electrically connected with a 2j-th first scan signal line comprises the 2j-th light emitting signal line.

14. The display panel according to claim 13, wherein an orthographic projection of the (2j−1)-th reference output line on the substrate is at least partially overlapped with orthographic projections of the first signal connection line and the (2j−1)-th reference signal line on the substrate, and the (2j−1)-th reference output line is electrically connected with the (2j−1)-th reference signal line; an orthographic projection of the 2j-th reference output line on the substrate is at least partially overlapped with orthographic projections of the second scan connection part, the second light emitting connection part and a 2j-th reference signal line on the substrate, and the 2j-th reference output line is electrically connected with the 2j-th reference signal line.

15. The display panel according to claim 5, wherein:
the drive circuit layer further comprises: a first signal connection line located in the first conductive layer, the first signal connection line is extended in the second direction and electrically connected with the (2j−1)-th third scan signal line and the 2j-th third scan signal line, respectively;
an orthographic projection of the first signal connection line on the substrate is at least partially overlapped with orthographic projections of the (2j−1)-th first scan output line and the 2j-th first scan output line on the substrate; and
an orthographic projection of the j-th third scan output line on the substrate is at least partially overlapped with an orthographic projection of the 2j-th third scan signal line on the substrate, and the j-th third scan output line is electrically connected with the 2j-th third scan signal line.

16. The display panel according to claim 15, wherein:
the drive circuit layer further comprises: a second signal connection line located at the first conductive layer, and a third signal connection line and a fourth signal connection line located at the second conductive layer, the second signal connection line is extended in the second direction, the third signal connection line and the fourth signal connection line are extended at least partially in the first direction, the second signal connection line is located on a side of the first signal connection line away from the display region;
an orthographic projection of the second signal connection line on the substrate is at least partially overlapped with orthographic projections of the (2j−1)-th first scan output line, the 2j-th first scan output line, the j-th second scan output line, the j-th third scan output line, the third signal connection line and the fourth signal connection line on the substrate, and the second signal connection line is electrically connected with the j-th second scan output line, the third signal connection line and the fourth signal connection line respectively;
an orthographic projection of the third signal connection line on the substrate is at least partially overlapped with orthographic projections of the first signal connection line and the (2j−1)-th second scan signal line on the substrate, and the third signal connection line is electrically connected with the (2j−1)-th second scan signal line; and
an orthographic projection of the fourth signal connection line on the substrate is at least partially overlapped with orthographic projections of the first signal connection line and the 2j-th second scan signal line on the substrate, and the fourth signal connection line is electrically connected with the 2j-th second scan signal line.

17. The display panel according to claim 16, wherein:
the drive circuit layer further comprises: a fifth signal connection line located at the first conductive layer, and a sixth signal connection line and a seventh signal connection line located at the second conductive layer, the fifth signal connection line is extended in the second direction, the sixth signal connection line and the seventh signal connection line are extended at least partially in the first direction, the fifth signal connection line is located on a side of the second signal connection line away from the display region;
an orthographic projection of the fifth signal connection line on the substrate is at least partially overlapped with orthographic projections of the (2j−1)-th first scan output line, the 2j-th first scan output line, the j-th second scan output line, the j-th third scan output line, the j-th light emitting output line, the sixth signal connection line and the seventh signal connection line on the substrate, and the fifth signal connection line is electrically connected with the j-th light emitting output line, the sixth signal connection line and the seventh signal connection line respectively;
an orthographic projection of the sixth signal connection line on the substrate is at least partially overlapped with orthographic projections of the first signal connection line, the second signal connection line and the (2j−1)-th light emitting signal line on the substrate, and the sixth signal connection line is electrically connected with the (2j−1)-th light emitting signal line; and
an orthographic projection of the seventh signal connection line on the substrate is at least partially overlapped with orthographic projections of the first signal connection line, the second signal connection line and the 2j-th light emitting signal line on the substrate, and the seventh signal connection line is electrically connected with the 2j-th light emitting signal line.

18. The display panel according to claim 17, wherein:
the first signal lines electrically connected with the i-th first scan signal line comprises: the i-th first scan output line; and
the second signal lines corresponding to the first signal lines electrically connected with the (2j−1)-th first scan signal line comprise the first signal connection line, the second signal connection line and the fifth signal connection line, and the second signal lines corresponding to the first signal lines electrically connected with the 2j-th first scan signal line comprise the first signal connection line, the second signal connection line and the fifth signal connection line.

19. The display panel according to claim 18, wherein an orthographic projection of the (2j−1)-th reference output line on the substrate is at least partially overlapped with orthographic projections of the first signal connection line, the second signal connection line, the fifth signal connection line and the (2j−1)-th reference signal line on the substrate, and the (2j−1)-th reference output line is electrically connected with the (2j−1)-th reference signal line;
an orthographic projection of the 2j-th reference output line on the substrate is at least partially overlapped with orthographic projections of the first signal connection line, the second signal connection line, the fifth signal connection line and the 2j-th reference signal line on the substrate, and the 2j-th reference output line is electrically connected with the 2j-th reference signal line.

20-27. (canceled)

28. A display apparatus, comprising: the display panel of claim 1.
